(19) United States
(12) Patent Application Publication
(10) Pub. No.: US 2017/0288144 A1
(43) Pub. Date: Oct. 5, 2017

(54) ALL SOLID STATE SECONDARY BATTERY, SOLID ELECTROLYTE COMPOSITION USED THEREFOR, ELECTRODE SHEET FOR BATTERY, AND METHOD FOR MANUFACTURING ELECTRODE SHEET FOR BATTERY AND ALL SOLID STATE SECONDARY BATTERY

(71) Applicant: FUJIFILM Corporation, Tokyo (JP)

(72) Inventors: Masaomi MAKINO, Kanagawa (JP); Hiroaki MOCHIZUKI, Kanagawa (JP); Tomonori MIMURA, Kanagawa (JP); Katsuhiko MEGURO, Kanagawa (JP)

(73) Assignee: FUJIFILM Corporation, Tokyo (JP)

(21) Appl. No.: 15/628,876

(22) Filed: Jun. 21, 2017

Related U.S. Application Data
(63) Continuation of application No. PCT/JP2016/052821, filed on Jan. 29, 2016.

(30) Foreign Application Priority Data
Feb. 4, 2015 (JP) 2015-019990

(51) Int. Cl. H01L 51/00; C01F 17/00; C08F 10/00; H01M 10/0565; C08F 38/02

(52) U.S. Cl. CPC H01L 51/0041; H01M 10/0565; C08F 38/02; C08F 10/00; C01F 17/0012

(57) ABSTRACT

Provided are an all solid state secondary battery having a positive electrode active material layer, an inorganic solid electrolyte layer, and a negative electrode active material layer in this order, in which at least one layer of the positive electrode active material layer, the inorganic solid electrolyte layer, or the negative electrode active material layer includes a polymer and an inorganic solid electrolyte, in which the polymer is a crosslinking polymer having both of hetero atoms and carbon-carbon unsaturated bonds not contributing to aromaticity in a main chain, and the inorganic solid electrolyte contains a metal belonging to Group I or II of the periodic table and has an ion conductivity of the metal being contained, a solid electrolyte composition being used therefor, an electrode sheet for a battery, and a method for manufacturing an electrode sheet for a battery and an all solid state secondary battery.

### CROSS-REFERENCE TO RELATED APPLICATIONS

This application is a Continuation of PCT International Application No. PCT/JP2016/052821 filed on Jan. 29, 2016, which claims priority under 35 U.S.C. §119 (a) to Japanese Patent Application No. JP2015-019990 filed in Japan on Feb. 4, 2015. Each of the above applications is hereby expressly incorporated by reference, in its entirety, into the present application.

### BACKGROUND OF THE INVENTION

### 1. Field of the Invention

The present invention relates to an all solid state secondary battery, a solid electrolyte composition used therefor, an electrode sheet for a battery, and a method for manufacturing an electrode sheet for a battery and an all solid state secondary battery.

### 2. Description of the Related Art

For lithium ion batteries, electrolytic solutions have been used. Attempts are underway to produce all solid state secondary batteries in which all constituent materials are solid by replacing electrolytic solutions with solid electrolytes. Reliability in terms of integrated performances of batteries is an advantage of techniques of using inorganic solid electrolytes. For example, to electrolytic solutions being used for lithium ion secondary batteries, flammable materials such as carbonate-based solvents are applied as media. In spite of the employment of a variety of safety measures, there may be a concern that disadvantages may be caused during overcharging and the like, and there is a demand for additional efforts. All solid state secondary batteries in which non-flammable electrolytes can be used are considered as a fundamental solution thereof.

Another advantage of all solid state secondary batteries is the suitability for increasing energy density by means of the stacking of electrodes. Specifically, it is possible to produce batteries having a structure in which electrodes and electrolytes are directly arranged in series. At this time, metal packages sealing battery cells and copper wires or bus-bars connecting battery cells may not be provided, and thus the energy density of batteries can be significantly increased. In addition, favorable compatibility with positive electrode materials capable of increasing potentials and the like can be considered as advantages.

From the viewpoint of the respective advantages described above, active development of next-generation lithium ion secondary batteries is underway (New Energy and Industrial Technology Development Organization (NEDO), Fuel Cell and Hydrogen Technologies Development Department, Electricity Storage Technology Development Section, “NEDO 2008 Roadmap for the Development of Next Generation Automotive Battery Technology 2008” (June, 2009)). Meanwhile, in inorganic all solid state secondary batteries, since hard solid electrolytes are used, improvement is also required. For example, interface resistances increase among solid particles, between solid particles and agglomerates, and the like, and thus techniques of using acrylic binders, fluorine-containing binders, rubber binders such as butadiene, or the like are proposed in order to improve interface resistances (JP2012-212652A and the like).

JP2011-76792A proposes an all solid state secondary battery in which a sulfide solid electrolyte material which substantially does not have any crosslinking structures and a hydrophobic polymer binding the sulfide solid electrolyte material are used in order to suppress an increase in battery resistances attributed to the deterioration of the sulfide solid electrolyte material.

### SUMMARY OF THE INVENTION

Binders for which the polymer disclosed by JP2012-212652A and JP2011-76792A is used are still not favorable enough to satisfy the continuously intensifying need for the improvement of the performance of lithium ion batteries, and there is a demand for additional improvement.

Therefore, an object of the present invention is to provide an all solid state secondary battery capable of realizing a high ion conductivity (high battery voltage) and high cycle characteristics by suppressing an increase in the interface resistance between inorganic solid electrolytes and active materials, a solid electrolyte composition being used therefor, an electrode sheet for a battery, and a method for manufacturing an electrode sheet for a battery and an all solid state secondary battery.

Regarding materials being combined with inorganic solid electrolytes, the present inventors repeated studies and experiments from a variety of aspects in consideration of the above-described object. As a result, it was found that, when a combination of an electrolytic crosslinking polymer containing carbon-carbon unsaturated bonds not contributing to aromaticity described below and hetero atoms and an inorganic solid electrolyte is used in the main chain, a favorable ion conductivity (favorable battery voltage) is obtained, and the cycle characteristics can be improved. The present invention was completed on the basis of this finding.

The object of the present invention was achieved by the following means.

(1) An all solid state secondary battery comprising a positive electrode active material layer; an inorganic solid electrolyte layer; and a negative electrode active material layer in this order, in which at least one layer of the positive electrode active material layer, the inorganic solid electrolyte layer, or the negative electrode active material layer includes a polymer and an inorganic solid electrolyte, in which the polymer is a crosslinking polymer having both of hetero atoms and carbon-carbon unsaturated bonds not contributing to aromaticity in a main chain, and the inorganic solid electrolyte contains a metal belonging to Group I or II of the periodic table and has an ion conductivity of the metal being contained.

(2) The all solid state secondary battery according to (1), in which the crosslinking polymer has at least one structural unit selected from Formula (1) or (2) below in the main chain,

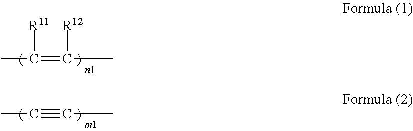

In Formula (1) or (2), R¹¹ and R¹² each independently represent a hydrogen atom, an alkyl group, an aryl group, or a heteroaryl group. R¹¹ and R¹² may be bonded to each other and form a ring not having aromaticity. Stereoisomerism of R¹¹ and R¹² may be any one of cis and trans. n1 and m1 each independently represent an integer of 1 or more and 10 or less.

(3) The all solid state secondary battery according to (1) or (2), in which the crosslinking polymer has at least one structural unit selected from Formula (1a) or (2a) below in the main chain,

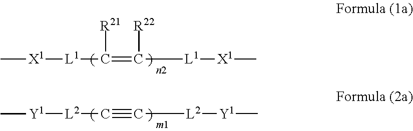

In Formula (1a) or (2a), R²¹ and R²² each independently represent a hydrogen atom, an alkyl group, an aryl group, or a heteroaryl group. R²¹ and R²² may be bonded to each other and form a ring not having aromaticity. Stereoisomerism of R²¹ and R²² may be any one of cis and trans. n2 and m2 each independently represent an integer of 1 or more and 5 or less. L¹ and L² each independently represent a single bond or a divalent linking group. Two L¹'s or two L²'s may be bonded to each other and form a ring not having aromaticity. X¹ and Y¹ each independently represent an oxygen atom, >NR^{N}, >CO, or a combination thereof. R^{N} represents a hydrogen atom or an alkyl group. R^{N} and L¹ or R^{N} and L² may be bonded to each other and form a ring not having aromaticity. A plurality of L¹'s, L²'s, X¹'s, and Y¹'s may be identical to or different from each other.

(4) The all solid state secondary battery according to any one of (1) to (3), in which the number of the carbon-carbon unsaturated bonds not contributing to aromaticity in the main chain of the crosslinking polymer is set to one in the case of a double bond or two in the case of a triple bond, and an unsaturated bond percentage calculated using Expression (3) below has a relationship of Expression (4) below.

Unsaturated bond percentage=(the total number of the carbon-carbon unsaturated bonds not contributing to aromaticity in the main chain)/(the total number of all carbon-carbon bonds forming the main chain)×100 Expression (3)

0.1%<unsaturated bond percentage<50% Expression (4)

(5) The all solid state secondary battery according to any one of (1) to (4), in which the crosslinking polymer has a bond represented by Formula (5) blow in the main chain.

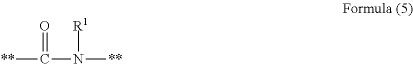

In Formula (5), R¹ represents a hydrogen atom, an alkyl group, an aryl group, or a group being bonded to the nitrogen atom in Formula (5) through a carbonyl group. R¹ may be bonded to an organic group to which C(═O) is linked and form a ring. ** represents a linking portion.

(6) The all solid state secondary battery according to any one of (1) to (5), in which the crosslinking polymer is polyurethane.

(7) The all solid state secondary battery according to any one of (1) to (6), in which the crosslinking polymer includes at least one functional group selected from a group of functional groups (1).

Group of Functional Groups (1)

A carboxy group, a sulfonic acid group, a phosphoric acid group, a hydroxy group, —CONR^{NA}₂, a cyano group, NR^{NA}₂, a mercapto group, an epoxy group, and a (meth)acryl group. R^{NA} represents a hydrogen atom, an alkyl group, or an aryl group.

(8) The all solid state secondary battery according to any one of (1) to (7), in which a mass average molecular weight of the crosslinking polymer is 10,000 or more and less than 500,000.

(9) The all solid state secondary battery according to any one of (1) to (8), in which a glass transition temperature of the crosslinking polymer is lower than 50° C.

(10) The all solid state secondary battery according to any one of (1) to (8), in which at least one layer of the positive electrode active material layer, the negative electrode active material layer, or the inorganic solid electrolyte layer further contains a lithium salt.

(11) The all solid state secondary battery according to any one of (1) to (10), in which the inorganic solid electrolyte is a sulfide-based inorganic solid electrolyte.

(12) The all solid state secondary battery according to any one of (1) to (10), in which the inorganic solid electrolyte is an oxide-based inorganic solid electrolyte.

(13) The all solid state secondary battery according to (12), in which the inorganic solid electrolyte is selected from compounds of formulae below.

LiₓₐLa_{ya}TiO₃

xa=0.3 to 0.7, ya=0.3 to 0.7
Li₇La₃Zr₂O₁₂
Li_{3.5}Zn_{0.25}GeO₄
LiTi₂P₃O₁₂
Li_{1+xb+yb}(Al, Ga)_{xb}(Ti, Ge)_{2-xb}Si_{yb}P_{3-yb}O₁₂
   0≦xb≦1, 0≦yb≦1
Li₃PO₄
LiPON
LiPOD
   D is at least one selected from Ti, V, Cr, Mn, Fe, Co, Ni, Cu, Zr, Nb, Mo, Ru, Ag, Ta, W, Pt, or Au
LiAON
   A is at least one selected from Si, B, Ge, Al, C, or Ga.

(14) A solid electrolyte composition being used for an all solid state secondary battery, comprising: a crosslinking polymer having both of hetero atoms and carbon-carbon unsaturated bonds not contributing to aromaticity in a main chain; and an inorganic solid electrolyte containing a metal belonging to Group I or II of the periodic table and having an ion conductivity of the metal being contained.

(15) The solid electrolyte composition according to (14), comprising: 0.1 parts by mass or more and 20 parts by mass or less of the crosslinking polymer with respect to 100 parts by mass of the inorganic solid electrolyte.

(16) An electrode sheet for a battery, in which a film of the solid electrolyte composition of (14) or (15) is formed on a metal foil.

(17) A method for manufacturing an electrode sheet for a battery, in which a film of the solid electrolyte composition of (14) or (15) is formed on a metal foil.

(18) A method for manufacturing an all solid state secondary battery, in which an all solid state secondary battery is manufactured using the electrode sheet for a battery according to (16).

(19) An all solid state secondary battery which is formed by crosslinking the crosslinking polymer by charging or discharging the all solid state secondary battery according to any one of (1) to (13) at least once.

In the present specification, numerical ranges expressed using “to” include numerical values before and after the “to” as the lower limit value and the upper limit value.

In the present specification, when a plurality of substituents or linking groups represented by specific symbols are present or a plurality of substituents or the like are simultaneously or selectively determined (similarly, the number of substituents is determined), the respective substituents and the like may be identical to or different from each other. In addition, when come close to each other, a plurality of substituents or the like may be bonded or condensed to each other and form a ring.

In addition, regarding “(meth)” used to express (meth)acryloyl groups, (meth)acryl groups, or resins, for example, (meth)acryloyl groups are collective terms of acryloyl groups and methacryloyl groups and may be any one or both thereof.

The all solid state secondary battery of the present invention exhibits an excellent ion conductivity (favorable battery voltage) and excellent cycle characteristics.

In addition, the solid electrolyte composition and the electrode sheet for a battery of the present invention enable the manufacturing of all solid state secondary batteries having the above-described excellent performance. In addition, according to the manufacturing method of the present invention, it is possible to efficiently manufacture the electrode sheet for a battery and the all solid state secondary battery of the present invention having the above-described excellent performance.

The above-described and other characteristics and advantages of the present invention will be further clarified by the following description with appropriate reference to the accompanying drawings.

### BRIEF DESCRIPTION OF THE DRAWINGS

FIG. 1 is a schematic cross-sectional view illustrating an all solid state lithium ion secondary battery according to a preferred embodiment of the present invention.

FIG. 2 is a vertical cross-sectional view schematically illustrating a testing device used in examples.

### DESCRIPTION OF THE PREFERRED EMBODIMENTS

An all solid state secondary battery of the present invention is an all solid state secondary battery having a positive electrode active material layer; an inorganic solid electrolyte layer; and a negative electrode active material layer in this order, in which at least one layer of the positive electrode active material layer, the inorganic solid electrolyte layer, or the negative electrode active material layer has a crosslinking polymer containing both of hetero atoms and carbon-carbon unsaturated bonds not contributing to aromaticity and an inorganic solid electrolyte in a main chain. Hereinafter, a preferred embodiment thereof will be described.

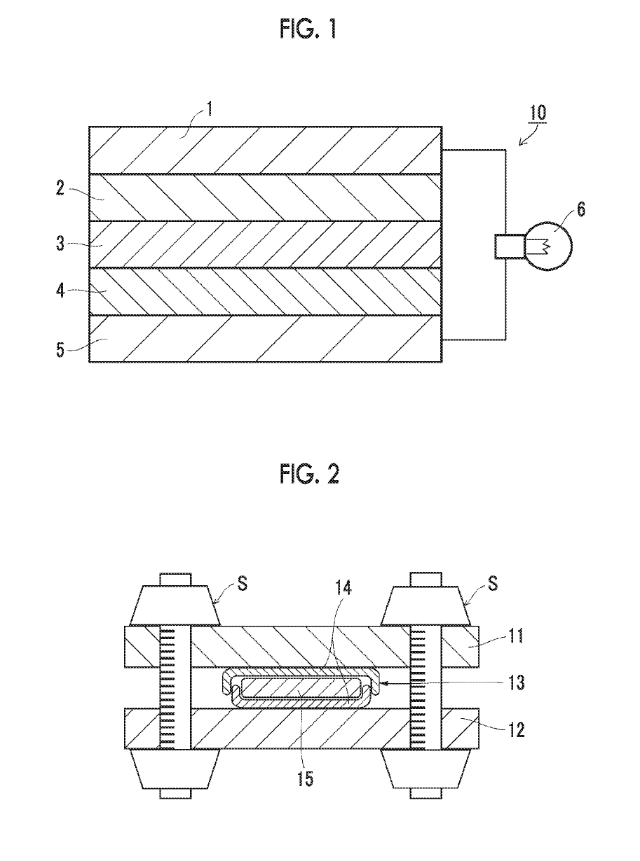

FIG. 1 is a schematic cross-sectional view illustrating an all solid state lithium ion secondary battery (lithium ion secondary battery) according to a preferred embodiment of the present invention. When described from the negative electrode side, an all solid state secondary battery 10 of the present embodiment has a negative electrode collector 1, a negative electrode active material layer 2, a solid electrolyte layer 3, a positive electrode active material layer 4, and a positive electrode collector 5. The respective layers have a structure in which the layers are in contact with each other and laminated together. Due to the above-described structure, during charging, electrons (e⁻) are supplied to the negative electrode side, and lithium ions (Li⁺) are accumulated on the negative electrode side. On the other hand, during discharging, the lithium ions (Li⁺) accumulated on the negative electrode return to the positive electrode side, and electrons are supplied to an operation portion 6. In an example illustrated in the drawing, an electric bulb is exemplified as the operation portion 6 and is lighted by discharging. A solid electrolyte composition of the present invention is preferably used as a material used to form the negative electrode active material layer, the positive electrode active material layer, and the solid electrolyte layer and, among these, is preferably used to form the negative electrode active material layer or the positive electrode active material layer.

The thicknesses of the positive electrode active material layer 4, the solid electrolyte layer 3, and the negative electrode active material layer 2 are not particularly limited, but are preferably 1,000 μm or less, more preferably 1 to 1,000 μm, and still more preferably 3 to 400 μm in consideration of the dimensions of ordinary batteries.

Hereinafter, a solid electrolyte composition that can be preferably used to manufacture the all solid state secondary battery of the present invention will be described.

The solid electrolyte composition of the present invention has a crosslinking polymer containing both of hetero atoms and carbon-carbon unsaturated bonds not contributing to aromaticity in a main chain and an inorganic solid electrolyte in a main chain.

The solid electrolyte composition of the present invention is preferably used for solid electrolytes in all solid state secondary batteries and more preferably used for inorganic solid electrolytes.

<Solid Electrolyte Composition>

(Inorganic Solid Electrolyte)

The inorganic solid electrolyte refers to a solid electrolyte made of an inorganic substance, and the solid electrolyte refers to a solid-form electrolyte capable of migrating ions therein. From this viewpoint, there are cases in which the inorganic solid electrolyte will be referred to as the ion-conductive inorganic solid electrolyte in consideration of distinction from lithium salts which are electrolyte salts described below (supporting electrolytes).

The inorganic solid electrolyte does not include organic substances (carbon atoms) and is thus clearly differentiated from organic solid electrolytes, high-molecular electrolytes represented by polyethylene oxide (PEO), and organic electrolyte salts represented by lithium bistrifluoromethanesulfonylimide (LiTFSI) and the like. In addition, the inorganic solid electrolyte is solid in a steady state and is thus not dissociated or liberated into cations and anions. Therefore, the inorganic solid electrolyte is also clearly differentiated from inorganic electrolyte salts that are disassociated or liberated into cations and anions in electrolytic solutions or polymers (LiPF₆, LiBF₄, LiFSI [lithium bis(fluorosulfonyl)imide], LiCl, and the like). The inorganic solid electrolyte is not particularly limited as long as the inorganic solid electrolyte includes a metal belonging to Group I or II of the periodic table and has a conductivity of these metal ions (preferably lithium ions) and generally does not have an electron conductivity.

The inorganic solid electrolyte being used in the present invention has a conductivity of ions of a metal belonging to Group I or II of the periodic table. As the inorganic solid electrolyte, it is possible to appropriately select and use solid electrolyte materials being applied to this kind of products. Typical examples of the inorganic solid electrolyte include (i) sulfide-based inorganic solid electrolytes and (ii) oxide-based inorganic solid electrolytes.

(i) Sulfide-Based Inorganic Solid Electrolytes

Sulfide-based inorganic solid electrolytes (hereinafter, also referred to simply as sulfide solid electrolytes) are preferably inorganic solid electrolytes which contain sulfur atoms (S), have an ion conductivity of metals belonging to Group I or II of the periodic table, and has electron-insulating properties. Examples thereof include lithium ion-conductive inorganic solid electrolytes satisfying a compositional formula represented by Formula (A) below.

Liₐ₁M_{b1}P_{c1}S_{d1} (A)

In Formula (A), M represents an element selected from B, Zn, Si, Cu, Ga, and Ge. a1 to d1 represent the compositional fractions of the respective elements, and a1:b1:c1:d1 respectively satisfy 1 to 12:0 to 1:1:2 to 9.

Regarding the compositional fractions of Li, M, P, and S in Formula (A), it is preferable that b1 is zero, it is more preferable that b1 is zero and the compositional fraction (a1:c1:d1) of a1, c1, and d1 is 1 to 9:1:3 to 7, and it is still more preferable that b1 is zero and a1:c1:d1 is 1.5 to 4:1:3.25 to 4.5. The compositional fractions of the respective elements can be controlled by adjusting the amounts of raw material compounds blended during the manufacturing of the sulfide-based solid electrolyte.

The sulfide-based solid electrolyte may be non-crystalline (glass) or crystallized (made into glass ceramic) or may be only partially crystallized.

The ratio between Li₂S and P₂S₅ in Li—P—S-based glass and Li—P—S-based glass ceramic is preferably 65:35 to 85:15 and more preferably 68:32 to 75:25 in terms of the molar ratio between Li₂S:P₂S₅. When the ratio between Li₂S and P₂S₅ is set in the above-described range, it is possible to increase lithium ion conductivity. Specifically, the lithium ion conductivity can be preferably set to 1×10⁻² S/m or more and more preferably set to 0.1 S/m or more.

Specific examples of the compound include compounds formed using a raw material composition containing, for example, Li₂S and a sulfide of an element of Groups XIII to XV.

More specific examples thereof include Li₂S—P₂S₅. Li₂S—GeS₂, Li₂S—GeS₂—ZnS, Li₂S—Ga₂S₃, Li₂S—GeS₂—Ga₂S₃, Li₂S—GeS₂—P₂S₅, Li₂S—GeS₂—Sb₂S₅, Li₂S—GeS₂—Al₂S₃, Li₂S—SiS₂, Li₂S—Al₂S₃, Li₂S—SiS₂—Al₂S₃, Li₂S—SiS₂—P₂S₅, Li₂S—SiS₂—LiI, Li₂S—SiS₂—Li₄SiO₄, Li₂S—SiS₂—Li₃PO₄, and Li₁₀GeP₂S₁₂. Among these, crystalline or amorphous raw material compositions made of Li₂S—P₂S₅, Li₂S—GeS₂—Ga₂S₃, Li₂S—GeS₂—P₂S₅, Li₂S—SiS₂—P₂S₅, Li₂S—SiS₂—Li₄SiO₄, or Li₂S—SiS₂—Li₃PO₄ are preferred due to their high lithium ion conductivity.

Examples of a method for synthesizing sulfide solid electrolyte materials using the above-described raw material compositions include an amorphorization method. Examples of the amorphorization method include a mechanical milling method and a melting quenching method. Among these, the mechanical milling method is preferred since treatments at normal temperature become possible, and it is possible to simplify manufacturing steps.

The sulfide solid electrolyte can be synthesized with reference to, for example, non-patent documents such as T. Ohtomo, A. Hayashi, M. Tatsumisago, Y. Tsuchida, S. Hama, K. Kawamoto, Journal of Powder Sources, 233, (2013), pp. 231 to 235 and A. Hayashi, S. Hama, H. Morimoto, M. Tatsumisago, T. Minami, Chem. Lett., (2001), pp. 872 and 873.

(ii) Oxide-Based Inorganic Solid Electrolytes

Oxide-based inorganic solid electrolytes (hereinafter, also referred to simply as oxide-based solid electrolytes) are preferably inorganic solid electrolytes which contain oxygen atoms (O), include a metal belonging to Group I or II of the periodic table, has an ion conductivity, and has electron-insulating properties.

Specific examples thereof include LiₓₐLa_{ya}TiO₃[xa=0.3 to 0.7 and ya=0.3 to 0.7] (LLT), Li₇La₃Zr₂O₁₂ (LLZ, lithium lanthanum zirconate), Li_{3.5}Zn_{0.25}GeO₄ having a lithium super ionic conductor (LISICON)-type crystal structure, LiTi₂P₃O₁₂ having a natrium super ionic conductor (NASICON)-type crystal structure, Li_{1+xb+yb}(Al, Ga)_{xb}(Ti, Ge)_{2-xb}Si_{yb}P_{3-yb}O₁₂ (here, 0≦xb≦1 and 0≦yb≦1), and Li₇La₃Zr₂O₁₂ having a garnet-type crystal structure.

In addition, phosphorus compounds including Li, P, and O are also preferred. Examples thereof include lithium phosphate (LI₃PO₄), LiPON in which part of oxygen atoms in lithium phosphate are substituted with nitrogen atoms, and LiPOD (D represents at least one element selected from Ti, V, Cr, Mn, Fe, Co, Ni, Cu, Zr, Nb, Mo, Ru, Ag, Ta, W, Pt, Au, or the like). In addition, LiAON (A represents at least one selected from Si, B, Ge, Al, C, Ga, or the like) and the like can also be preferably used.

Among these, Li_{1+xb+yb}(Al, Ga)_{xb}(Ti, Ge)_{2-xb}Si_{yb}P_{3-yb}O₁₂ (here, 0≦xb≦1 and 0≦yb≦1) is preferred since Li_{1+xb+yb}(Al, Ga)_{xb}(Ti, Ge)_{2-xb}Si_{yb}P_{3-yb}O₁₂ has a high lithium ion conductivity, is chemically stable, and can be easily handled. These compounds may be used singly or two or more compounds may be used in combination.

The lithium ion conductivity of the oxide-based solid electrolyte is preferably 1×10⁻⁴ S/m or more, more preferably 1×10⁻³ S/m or more, and still more preferably 5×10⁻³ S/m or more.

The average particle diameter of the inorganic solid electrolyte is not particularly limited, but is preferably 0.01 μm or more and more preferably 0.1 μm or more. The upper limit is preferably 100 μm or less and more preferably 50 μm or less. The average particle diameter of the inorganic solid electrolyte is measured using a method described in the section of examples described below.

When the satisfaction of both of battery performance and an effect of reducing and maintaining the interface resistance is taken into account, the concentration of the inorganic solid electrolyte in the solid electrolyte composition is preferably 50% by mass or more, more preferably 80% by mass or more, and still more preferably 90% by mass or more with respect to 100% by mass of the solid component. From the same viewpoint, the upper limit is preferably 99.9% by mass or less, more preferably 99% by mass or less, and still more preferably 98% by mass or less.

Meanwhile, in the present specification, the solid component refers to a component that does not volatilize or evaporate and thus disappear when dried at 170° C. for six hours, and typically, refers to a component other than dispersion media described below.

(Polymer)

The polymer being used in the present invention is a polymer having both of hetero atoms and carbon-carbon unsaturated bonds not contributing to aromaticity in the main chain.

The polymer is capable of forming a crosslinking structure by means of electrolytic oxidation polymerization or electrolytic reduction polymerization when having carbon-carbon unsaturated bonds not contributing to aromaticity in the main chain and, furthermore, is capable of effectively exhibiting an excellent ion conductivity (favorable battery voltage) and excellent cycle characteristics when additionally having hetero atoms in the main chain.

In the polymer in the present invention, it is preferable that a crosslinking reaction attributed to the carbon-carbon unsaturated bonds being included in the main chain is caused by electrolytic oxidation polymerization or electrolytic reduction polymerization. This preferred polymer is an electrolytic crosslinking polymer forming a crosslinking structure by means of electrolytic oxidation polymerization or electrolytic reduction polymerization.

Meanwhile, the crosslinking polymer is a polymer having at least two polymerizable groups such as the carbon-carbon unsaturated bonds not contributing to aromaticity in one molecule.

Hereinafter, the polymer in the present invention will also be referred to simply as the polymer, however, for convenience, will be representatively referred to as the electrolytic crosslinking polymer forming a crosslinking structure by means of electrolytic oxidation polymerization or electrolytic reduction polymerization in the description.

The polymer being used in the present invention plays a role of a binder that is arbitrarily combined with an additive or the like and is thus bonded to the inorganic solid electrolyte.

Here, the carbon-carbon unsaturated bond not contributing to aromaticity which is used in the present specification refers to a carbon-carbon unsaturated bond in chemical structures not exhibiting aromaticity, and examples thereof include carbon-carbon unsaturated bonds in aliphatic compounds and alicyclic compounds. That is, the carbon-carbon unsaturated bond not contributing to aromaticity does not include any carbon-carbon unsaturated bonds (including carbon-carbon unsaturated bonds exhibiting electronic behaviors such as aromatic compounds in cooperation with aromatic compounds) in aromatic compounds.

The electrolytic crosslinking polymer being used in the present invention preferably has at least one structural unit selected from Formula (1) or (2) below in the main chain.

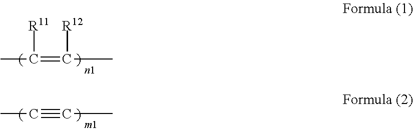

In Formulae (1) and (2), R¹¹ and R¹² each independently represent a hydrogen atom, an alkyl group, an aryl group, or a heteroaryl group. R¹¹ and R¹² may be bonded to each other and form a ring not having aromaticity. Stereoisomerism of R¹¹ and R¹² may be any one of cis and trans. n1 and m1 each independently represent an integer of 1 or more and 10 or less.

The number of carbon atoms in the alkyl group as R¹¹ and R¹² is preferably 1 to 12, more preferably 1 to 6, and still more preferably 1 to 4. Specific examples thereof include methyl, ethyl, propyl, isopropyl, butyl, t-butyl, and octyl.

The number of carbon atoms in the aryl group as R¹¹ and R¹² is preferably 6 to 22, more preferably 6 to 14, and still more preferably 6 to 10. Specific examples thereof include phenyl and naphthyl.

The heteroaryl group as R¹¹ and R¹² is preferably a group of a five-membered ring or six-membered ring having at least one oxygen atom, sulfur atom, or nitrogen atom as the ring-constituting atom, and the number of carbon atoms is preferably 1 to 22. Specific examples of heteroaryl rings constituting the heteroaryl group include pyrrole, pyridine, furan, pyran, and thiophene, and the heteroaryl ring may be condensed with a ring such as a benzene ring.

R¹¹ and R¹² are preferably hydrogen atoms or alkyl groups, more preferably hydrogen atoms or alkyl groups having 1 to 6 carbon atoms, and still more preferably hydrogen atoms or methyl.

Rings not having aromaticity which are formed by bonding R¹¹ and R¹² together may have an oxygen atom, a sulfur atom, or a nitrogen atom, the number of ring members is preferably 3 to 6, and the number of carbon atoms is preferably 1 to 22. Specific examples thereof include cyclohexene rings and cyclopentene rings.

n1 is preferably an integer of 1 or more and 5 or less, more preferably an integer of 1 or more and 3 or less, and still more preferably 1 or 2.

m1 is preferably an integer of 1 or more and 5 or less, more preferably an integer of 1 or more and 3 or less, and still more preferably 1 or 2.

The electrolytic crosslinking polymer being used in the present invention more preferably has at least one structural unit selected from Formula (1a) or (2a) below in the main chain.

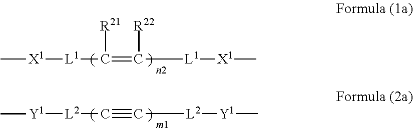

In Formulae (1a) and (2a), R²¹ and R²² each independently represent a hydrogen atom, an alkyl group, an aryl group, or a heteroaryl group. R²¹ and R²² may be bonded to each other and form a ring not having aromaticity. Stereoisomerism of R²¹ and R²² may be any one of cis and trans. n2 and m2 each independently represent an integer of 1 or more and 5 or less. L¹ and L² each independently represent a single bond or a divalent linking group. Two L¹'s or two L²'s may be bonded to each other and form a ring not having aromaticity. X¹ and Y¹ each independently represent an oxygen atom, an imino group (>NR^{N}), a carbonyl group (>CO), or a combination thereof. R^{N} represents a hydrogen atom or an alkyl group. R^{N} and L¹ or R^{N} and L² may be bonded to each other and form a ring not having aromaticity. A plurality of L¹'s, L²'s, X¹'s, and Y¹'s may be identical to or different from each other.

The alkyl group, the aryl group, and the heteroaryl group as R²¹ and R²² are the same as the alkyl group, the aryl group, and the heteroaryl group in Formulae (1) and (2), and preferred ranges thereof are also identical.

R²¹ and R²² are preferably hydrogen atoms or alkyl groups, more preferably hydrogen atoms or alkyl groups having 1 to 6 carbon atoms, and still more preferably hydrogen atoms or methyl.

Rings not having aromaticity which are formed by bonding R²¹ and R²² together are the same as the rings not having aromaticity which are formed by bonding R¹¹ and R¹² together), and a preferred range thereof is also identical.

n2 is preferably an integer of 1 or more and 3 or less and more preferably 1 or 2.

m2 is preferably an integer of 1 or more and 3 or less and more preferably 1 or 2.

The divalent linking group as L¹ and L² is preferably an alkylene group, an arylene group, a heteroarylene group, a cycloalkylene group, or a combination thereof.

The number of carbon atoms in the alkylene group as L¹ and L² is preferably 1 to 12, more preferably 1 to 6, and still more preferably 1 to 3.

The number of carbon atoms in the arylene group is preferably 6 to 22, more preferably 6 to 14, and still more preferably 6 to 10.

The heteroarylene group is preferably a group of a five-membered ring or six-membered ring having at least one oxygen atom, sulfur atom, or nitrogen atom as the ring-constituting atom, and the number of carbon atoms is preferably 2 to 20.

In addition, rings of the heteroarylene group may be single rings or condensed rings obtained by condensing a benzene ring, an aliphatic ring, or a hetero ring.

The number of carbon atoms in the cycloalkyl group is preferably 3 to 22, more preferably 6 to 14, and still more preferably 6 to 10, and rings being formed are preferably three to eight-membered rings, more preferably five to eight-membered rings, and still more preferably five or six-membered rings.

Examples of the combination of the alkylene group, the arylene group, the heteroarylene group, or the cycloalkylene group include an alkylene group-an arylene group, an alkylene group-a heteroarylene group, an alkylene group-a cycloalkylene group, and an arylene group-a cycloarylene group.

L¹ and L² each are independently preferably divalent linking groups, and an alkylene group, an arylene group, or a cycloalkylene group is preferred, and an alkylene group is more preferred.

Examples of rings not having aromaticity which are formed by bonding two L¹'s or two L²'s together include cyclic hydrocarbon structures having 5 to 10 carbon atoms. The number of carbon atoms is preferably 5 to 8 and more preferably 6. Meanwhile, the rings not having aromaticity which are formed by bonding two L¹'s or two L²'s together may have a substituent. Examples of the substituent include substituent T described below, and, among them, an alkyl group is preferred.

Preferred examples of the rings not having aromaticity which are formed by bonding two L¹'s or two L²'s together include cyclopentene rings, cyclohexene rings, and bicyclo[2,2,2]octo-7-ene rings.

The number of carbon atoms in the alkyl group as R^{N} is preferably 1 to 12, more preferably 1 to 6, and still more preferably 1 to 3.

R^{N} is preferably a hydrogen atom.

Examples of the combination of an oxygen atom, an imino group (>NR^{N}), or a carbonyl group (>CO) include imide bonds (—CO—NR^{N}—CO—).

X¹ and Y¹ are preferably oxygen atoms, imino groups (>NR^{N}), or carbonyl groups (>CO) and more preferably oxygen atoms.

Examples of rings not having aromaticity which are formed by bonding R^{N} and L¹ together or R^{N} and L² together include cyclic hydrocarbon structures having 5 to 10 carbon atoms. The number of carbon atoms is preferably 5 to 8 and more preferably 6. Meanwhile, the rings not having aromaticity which are formed by bonding R^{N} and L¹ together or R^{N} and L² together may have a substituent. Examples of the substituent include substituent T described below, and, among them, an alkyl group is preferred.

Preferred examples of the rings not having aromaticity which are formed by bonding R^{N} and L¹ together or R^{N} and L² together include lactam rings (α, γ, δ, ε-lactam and the like) and cyclic imide rings (succinimide, glutarimide, and the like).

The polymer being used in the present invention more preferably has at least one structural unit selected from Formula (1a) in the main chain.

When the polymer has the structural unit selected from Formula (1a) in the main chain, the structural unit represented by Formula (1a) is oxidized or reduced, and thus cation radicals or anion radicals are generated, and crosslinking is formed between the polymer main chains. Therefore, the ion conductivity and the cycle characteristics of all solid state secondary batteries are excellent, which is preferable.

In addition, the polymer also preferably has the structural unit selected from Formula (2a) in the main chain since oxidation or reduction is likely to occur.

In the electrolytic crosslinking polymer being used in the present invention, it is also preferable that the unsaturated bond percentage being computed using Expression (3) below has a relationship of Expression (4) below when the number of the carbon-carbon unsaturated bonds not contributing to aromaticity in the main chain of the crosslinking polymer is set to one in the case of a double bond or two in the case of a triple bond.

Unsaturated bond percentage=(the total number of the carbon-carbon unsaturated bonds not contributing to aromaticity in the main chain)/(the total number of all carbon-carbon bonds forming the main chain)×100 Expression (3)

0.1%<Unsaturated bond percentage<50% Expression (4)

Here, the main chain refers to the molecular chain of the longest trunk constituting the polymer.

When described using Exemplary Compound (A-2) described below as an example, this main chain of the polymer is illustrated as below by eliminating bonds and atoms not included in the main chain for convenience.

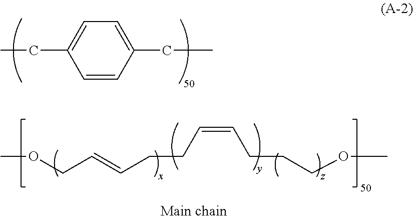

In Exemplary Compound (A-2), x, y, and z in the main chain represent molar fractions. The details of x, y, and z will be described below.

As is clear from the structure of the main chain in Exemplary Compound (A-2), carbon-carbon double bonds in components of Exemplary Compound (A-2) described below in which the molar fraction is z are not included in “the total number of the carbon-carbon unsaturated bonds not contributing to aromaticity in the main chain” and “the total number of all carbon-carbon bonds forming the main chain” in Expression (3).

In addition, all carbon-carbon bonds forming the main chain refer to all carbon-carbon bonds forming a ring structure in a case in which the main chain includes the ring structure.

For example, in the case of the following structural unit, when bonds and atoms not included in the main chain are eliminated for convenience as described above, all bonds forming the ring structure are left, and monovalent organic groups (substituents) or oxo groups (═O) being substituted into the ring are eliminated, carbon-carbon bonds forming the main chain are heavy line bonds.

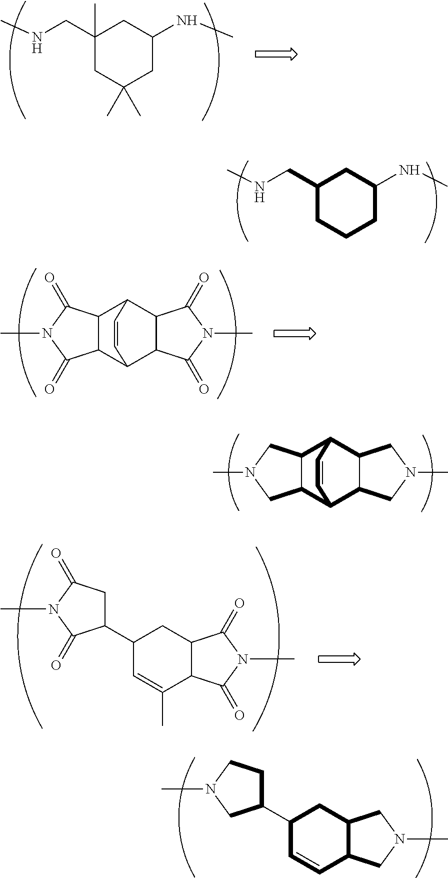

In addition, all carbon-carbon bonds refer to all bonds being formed between carbon-carbon and include both of carbon-carbon saturated bonds and unsaturated bonds. Meanwhile, for both of saturated bonds and unsaturated bonds, the number of bonds is considered as one in the calculation.

In addition, the molar fraction of the repeating unit of the polymer has no relationship with the molecular weight and is considered as the number of the repeating units in the calculation for convenience.

Hereinafter, the method for calculating the unsaturated bond percentage will be described using a specific polymer as an example.

1) Polymer not Having Side Chains

When described using Exemplary Compound (A-1) described below as an example, the total number of all carbon-carbon bonds forming the main chain is 8×50+3×50=550, the total number of the carbon-carbon unsaturated bonds not contributing to aromaticity in the main chain is 1×50=50, and the unsaturated bond percentage by Expression (3) is calculated to be 50/550×100=approximately 9.1%.

2) Polymer Having Ring Structure in Main Chain and not Having Carbon-Carbon Unsaturated Bonds in Side Chains

When described using Exemplary Compound (A-19) described below as an example, the total number of all carbon-carbon bonds forming the main chain is 12×50+14×50=1,300, the total number of the carbon-carbon unsaturated bonds not contributing to aromaticity in the main chain is 1×50=50, and the unsaturated bond percentage by Expression (3) is calculated to be 50/1,300×100=approximately 3.8%.

3) Polymer Having Ring Structure in Main Chain and Having Carbon-Carbon Unsaturated Bonds in Side Chains

Exemplary Compound (A-32) described below will be used as an example in the description. Here, x is set to 30, y is set to 10, and z is set to 10. The total number of all carbon-carbon bonds forming the main chain is 14×50+3×30+(4×30+4×10−1)×10+2×10=2,600, the total number of the carbon-carbon unsaturated bonds not contributing to aromaticity in the main chain is 1×30+(1×30+1×10)×10=430, and the unsaturated bond percentage by Expression (3) is calculated to be 430/2,600×100=approximately 16.5%.

4) Polymer Having Ring Structure in Main Chain and Having Triple Bonds as Carbon-Carbon Unsaturated Bonds

When described using Exemplary Compound (A-13) described below as an example, the total number of all carbon-carbon bonds forming the main chain is 3×50+7×50=500, the total number of the carbon-carbon unsaturated bonds not contributing to aromaticity in the main chain is 2×50=100, and the unsaturated bond percentage by Expression (3) is calculated to be 100/500×100=20%.

The unsaturated bond percentage is more preferably more than 1% and less than 40% and still more preferably more than 3% and less than 30%.

When all solid state secondary batteries are charged or discharged once or more, in the electrolytic crosslinking polymer being used in the present invention, mainly, the carbon-carbon unsaturated bonds not contributing to aromaticity in the main chain are electrolytic-oxidation-polymerized or electrolytic-reduction-polymerized due to the action of an electrolytic reaction, a crosslinking structure is formed, and the molecular weight increases.

The unsaturated bond percentage after the electrolytic reaction is preferably 0% to 20% and more preferably 0% to 10%.

In a preferred aspect of the present invention, during the manufacturing of all solid state secondary batteries, the solid electrolyte composition containing the electrolytic crosslinking polymer is dried and falls into a solid state. Therefore, the electrolytic crosslinking polymer is in a state in which molecular motion between an active material and the inorganic solid electrolyte is suppressed to a certain extent, and part of the carbon-carbon unsaturated bonds participates in a crosslinking reaction due to the action of the electrolytic reaction.

Among them, in the total number of the carbon-carbon unsaturated bonds not contributing to aromaticity in the main chain, the proportion of the total number of the unsaturated bonds participating in the crosslinking reaction after the electrolytic polymerization in the total number of the unsaturated bonds before the electrolytic polymerization [the total number of the unsaturated bonds participating in the crosslinking reaction after the electrolytic polymerization/the total number of the unsaturated bonds before the electrolytic polymerization×100] is preferably 5% to 80% and more preferably 10% to 60%.

Here, the number of the carbon-carbon unsaturated bonds not contributing to aromaticity in the main chain and the number of all carbon-carbon atoms forming the main chain in the electrolytic crosslinking polymer being used in the present invention can be computed using the following method.

First, the binder is removed from the all solid state battery by means of elution, and the binder structure is identified by means of ¹H NMR, ¹³C NMR (both are nuclear magnetic resonance), ESCA (X-ray photoelectron spectrometry), TOF-SIMS (time-of-flight secondary ion mass spectrometry), or the like. Subsequently, the number of carbon-carbon bonds forming the unsaturated bonds in the main chain and the amount of all carbon-carbon bonds forming the main chain can be identified by means of ¹H NMR or ¹³C NMR.

In addition, even in a case in which it is not possible to identify the structure, the unsaturated bonds can be identified from the iodine value, and the number of carbon atoms can be identified from the amount of carbon monoxide and carbon dioxide generated during combustion.

Meanwhile, the above-described computation method can be applied to both of the electrolytic crosslinking polymer before crosslinking and the electrolytic crosslinking polymer after crosslinking. The electrolytic crosslinking polymer before crosslinking can also be computed from the loading ratio of the monomer.

Generally, the polymer having the hetero atom and the carbon-carbon unsaturated bonds not contributing to aromaticity in the main chain can be provided with an increased molecular weight and synthesized by linking molecular chains by means of polycondensation reactions.

Specifically, when monomers being used in polycondensation reactions have the carbon-carbon unsaturated bonds not contributing to aromaticity in portions constituting the polymer main chain due to polycondensation, the carbon-carbon unsaturated bonds not contributing to aromaticity are incorporated into the polymer main chain due to polycondensation. In addition, when monomers being used in polycondensation reactions have functional groups including hetero atoms in the terminal or the like, these functional groups polycondense, and thus hetero atoms are incorporated into the polymer main chain.

Preferred examples of the hetero atoms in the main chain of the polymer being used in the present invention include oxygen atoms, nitrogen atoms, sulfur atoms, and the like.

The hetero atoms in the main chain of the polymer being used in the present invention form linking groups in the structural unit of the polymer, and examples of the linking groups include ester bonds (—C(═O)O—), amide bonds (—C(═O)NR—), imide bonds (—C(═O)NRC(═O)—), urethane bonds (—NRC(═O)O—), carbonate bonds (—OC(═O)O—), urea bonds (—NRC(═O)NR—), ether bonds (—O—), and sulfide bonds (—S—). Here, R in the respective linking groups represents a hydrogen atom or an organic group and may form a ring structure with a carbon skeleton being linked by —C(═O).

The organic group as R is preferably an alkyl group having 1 to 12 carbon atoms (preferably methyl, ethyl, propyl, isopropyl, butyl, t-butyl, or octyl), an aryl group having 6 to 12 carbon atoms (preferably phenyl or naphthyl), an aralkyl group having 7 to 12 carbon atoms (preferably benzyl or phenethyl), an acyl group having 1 to 10 carbon atoms (preferably formyl, acetyl, pivaloyl, or benzoyl), an alkylsulfonyl group having 1 to 12 carbon atoms (preferably methanesulfonyl, ethanesulfonyl, trifluoromethanesulfonyl, or nonafluorobutanesulfonyl), an arylsulfonyl group having 6 to 12 carbon atoms (preferably benzenesulfonyl or toluenesulfonyl), an alkoxycarbonyl group having 2 to 10 carbon atoms (preferably methoxycarbonyl, ethoxycarbonyl, or benzyloxycarbonyl), an aryloxycarbonyl group having 7 to 13 carbon atoms (preferably phenoxycarbonyl), or an alkenyl group having 2 to 12 carbon atoms (preferably aryl).

The electrolytic crosslinking polymer being used in the present invention preferably has, among them, a bond represented by Formula (5) below in the main chain.

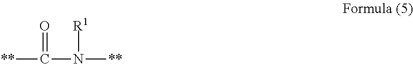

In Formula (5), R¹ represents a hydrogen atom, an alkyl group, an aryl group, or a group being bonded to the nitrogen atom in Formula (5) through a carbonyl group. R¹ may be bonded to an organic group (a group being bonded in the ** portion) to which C(═O) is linked and form a ring. ** represents a linking portion.

The alkyl group and the aryl group as R¹ are the same as the alkyl group and the aryl group in the organic group as R, and preferred ranges thereof are also identical.

Examples of the group being bonded to the nitrogen atom through a carbonyl group as R¹ include an acyl group, an alkoxycarbornyl group, an aryloxycarbonyl group, and the like, and, among these, the acyl group, the alkoxycarbonyl group, and the aryloxycarbonyl group are the same as the acyl group, the alkoxycarbornyl group, and the aryloxycarbonyl group in the organic group as R, and preferred ranges thereof are also identical.

Particularly, in a case in which R¹ is a group being bonded to the nitrogen atom through a carbonyl group, it is preferable that the group is bonded to an organic group to which C(═O) in Formula (5) is linked (a group being bonded in the ** portion) and form a ring.

Preferred examples of a bonding unit in which R or R¹ forms a ring structure with a carbon skeleton being linked by —C(═O) include structures illustrated below. In addition, the respective ring structures may have a substituent, and examples the substituent include the above-described organic groups.

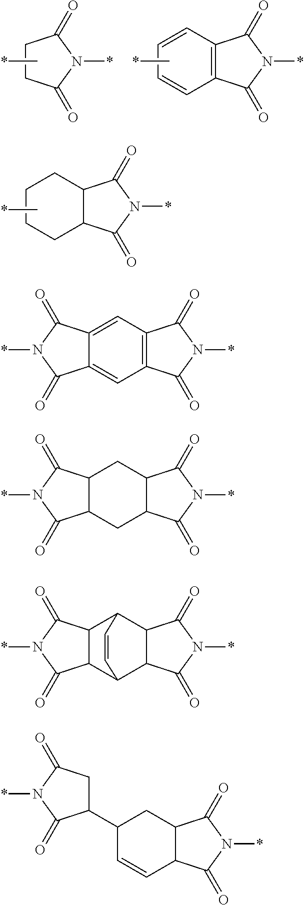

In the structures. * represents a bonding portion.

Meanwhile, in the structures, the double bond in the 7-ene portion of the bicycle[2,2,2]octo-7-ene ring in the middle structure of the second level and the double bond combined in the cyclohexene ring in the right structure of the second level are unsaturated bonds being counted as the carbon-carbon unsaturated bonds not contributing to aromaticity in the present invention.

R and R¹ are preferably, among these, hydrogen atoms.

The polymer being used in the present invention preferably has at least one bond selected from the group consisting of ester bonds, amide bonds, imide bonds, urethane bonds, carbonate bonds, urea bonds, ether bonds, or sulfide bonds in the main chain and more preferably has at least one bond selected from the group consisting of amide bonds, imide bonds, urethane bonds, or urea bonds having the bonding unit represented by Formula (5) in the main chain.

The polymer being used in the present invention still more preferably has at least an urethane bond in the main chain since the bonding properties of the polymer enhance and all solid state secondary batteries exhibit more favorable cycle characteristics.

Here, the polymer having at least one bond selected from the group consisting of ester bonds, amide bonds, imide bonds, urethane bonds, carbonate bonds, urea bonds, ether bonds, or sulfide bonds in the main chain refers to, that is, any one of polyester, polyamide, polyimide, polyurethane, polycarbonate, polyuria, polyether, polysulfide, a derivative thereof, and a combination thereof.

Hereinafter, the polymer being used in the present invention will be described in detail using raw materials such as monomers and the like forming a variety of bonds.

Polymer Having Ester Bond

Examples of a polymer having an ester bond include polyester, and the polyester can be synthesized by a condensation reaction between a corresponding dicarboxylic acid, an acid anhydride thereof, or a dicarboxylic acid chloride and a diol.

Examples of the dicarboxylic acid component include aliphatic dicarboxylic acids such as malonic acid, succinic acid, glutaric acid, adipic acid, sebacic acid, pimelic acid, suberic acid, azelaic acid, undecanoic acid, undecadioic acid, dodecadionic acid, and dimer acid, 1,4-cyclohexanedicarboyxlic acid, paraxylylenedicarboxylic acid, metaxylylenedicarboxylic acid, terephthalic acid, isophthalic acid, 2,6-naphthalenedicarboxylic acid, 4,4′-diphenyldicarboxylic acid, and the like.

Specific examples of diol compounds include ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 3-methyl-1,5-pentenediol, 1,6-hexanediol, 2-butene-1,4-diol, 2,2,4-trimethyl-1,3-pentanediol, 1,4-bis-β-hydroxyethoxycyclohexane, cyclohexane dimethanol, tricyclodecane dimethanol, hydrogenated bisphenol A, hydrogenated bisphenol F, ethylene oxide adducts of bisphenol A, propylene oxide adducts of bisphenol A, ethylene oxide adducts of bisphenol F, propylene oxide adducts of bisphenol F, ethylene oxide adducts of hydrogenated bisphenol A, propylene oxide adducts of hydrogenated bisphenol A, hydroquinone dihydroxyethyl ether, p-xylylene glycol, dihydroxyethyl sulfone, bis(2-hydroxyethyl)-2,4-tolylene dicarbamate, 2,4-tolylene-bis(2-hydroxyethylcarbamide), bis(2-hydroxyethyl)-m-xylylene dicarbamate, bis(2-hydroxyethyl) isophthalate, 1,3-propanediol, 1,4-butanediol, 1,5-pentanediol, 1,6-hexanediol, 1,7-heptanediol, 1,8-octanediol, 1,10-decanediol, dimethylol propionate, 2-butene-1,4-diol, cis-2-butene-1,4-diol, trans-2-butene-1,4-diol,

catechol, resorcin, hydroquinone, 4-methylcatechol, 4-t-butylcatechol, 4-acetylcatechol, 3-methoxycatechol, 4-phenylcatechol, 4-methylresorcin, 4-ethylresorcin, 4-t-butylresorcin, 4-hexylresorcin, 4-chlororesorcin, 4-benzylresorcin, 4-acetylresorcin, 4-carbomethoxyresorcin, 2-methylresorcin, 5-methylresorcin, t-butylhydroquinone, 2,5-di-t-butylhydroquinone, 2,5-di-t-amylhydroquinone, tetramethylhydroquinone, tetrachlorohydroquinone, methylcarboaminohydroquinone, methylureidohydroquinone, methylthiohydroquinone, benzonorbornene-3,6-diol, bisphenol A, bisphenol S, 3,3′-dichlorobisphenol S, 4,4′-dihydroxybenzophenone, 4,4′-dihydroxybiphenyl, 4,4′-thiodiphenol, 2,2′-dihydroxydiphenylmethane, 3,4-bis(p-hydroxyphenyl)hexane, 1,4-bis(2-(p-hydroxyphenyl)propyl)benzene, bis(4-hydroxyphenyl)methylamine, 1,3-dihydroxynaphthalene, 1,4-dihydroxynaphthalene, 1,5-dihydroxynaphthalene, 2,6-dihydroxynaphthalene, 1,5-dihydroxyanthraquinone, 2-hydroxybenzyl alcohol, 4-hydroxybenzyl alcohol, 2-hydroxy-3,5-di-t-butylbenzyl alcohol, 4-hydroxy-3,5-di-t-butylbenzyl alcohol, 4-hydroxyphenethyl alcohol, 2-hydroxyethyl-4-hydroxybenzoate, 2-hydroxyethyl-4-hydroxyphenylacetate, resorcine mono-2-hydroxyethyl ether,

diethylene glycol, triethylene glycol, tetraethylene glycol, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, hexa-1,3-butylene glycol, polyethylene glycol having an average molecular weight of 200, polyethylene glycol having an average molecular weight of 400, polyethylene glycol having an average molecular weight of 600, polyethylene glycol having an average molecular weight of 1,000, polyethylene glycol having an average molecular weight of 1,500, polyethylene glycol having an average molecular weight of 2,000, polyethylene glycol having an average molecular weight of 3,000, polyethylene glycol having an average molecular weight of 7,500, polypropylene glycol having an average molecular weight of 400, polypropylene glycol having an average molecular weight of 700, polypropylene glycol having an average molecular weight of 1,000, polypropylene glycol having an average molecular weight of 2,000, polypropylene glycol having an average molecular weight of 3,000, polypropylene glycol having an average molecular weight of 4,000, and the like.

The diol compounds can also be procured from commercially available products.

Examples of polyether diol compounds include Sanyo Chemical Industries, Ltd. of PTMG650, PTMG1000, PTMG20000, PTMG3000, NEWPOL PE-61, NEWPOL PE-62, NEWPOL PE-64, NEWPOL PE-68, NEWPOL PE-71, NEWPOL PE-74, NEWPOL PE-75, NEWPOL PE-78, NEWPOL PE-108, NEWPOL PE-128, NEWPOL BPE-20, NEWPOL BPE-20F, NEWPOL BPE-20NK, NEWPOL BPE-20T, NEWPOL BPE-20G, NEWPOL BPE-40, NEWPOL BPE-60, NEWPOL BPE-100, NEWPOL BPE-180, NEWPOL BP-2P, NEWPOL BPE-23P, NEWPOL BPE-3P, NEWPOL BPE-5P, NEWPOL 50HB-100), NEWPOL 50HB-260, NEWPOL 50HB-400, NEWPOL 50HB-660, NEWPOL 50HB-2000, and NEWPOL 50HB-5100 all of which are trade names.

Examples of polyester diol compounds include POLYLITE series (manufactured by DIC Corporation), KURARAY POLYOL P series, KURARAY POLYOL F series, KURARAY POLYOL N series, KURARAY POLYOL PMNA series (manufactured by Kuraray Co., Ltd.), and PLACCEL series (manufactured by Daicel Corporation) all of which are trade names.

Examples of polycarbonate diol compounds include DURANOL series (manufactured by Asahi Kasei Corporation), ETERNACOLL series (manufactured by Ube Industries, Ltd.), PLACCEL CD series (manufactured by Daicel Corporation), and KURARAY POLYOL C series (manufactured by Kuraray Co., Ltd.) all of which are trade names.

Polymer Having Amide Bond

Examples of a polymer having an amide bond include polyamide, and the polyamide can be synthesized by a condensation reaction between a corresponding dicarboxylic acid, an acid anhydride thereof, or a dicarboxylic acid chloride and a diamine or a ring-opening polymerization reaction of lactam.

Examples of the diamine component include aliphatic diamines such as ethylene diamine, 1-methylethyldiamine, 1,3-propylenediamine, tetramethylenediamine, pentamethylenediamine, hexamethylenediamine, heptamethylenediamine, octamethylenediamine, nonamethylenediamine, decamethylenediamine, undecamethylenediamine, and dodecamethylenediamine and additionally include cyclohexane diamine, bis(4,4′-aminohexyl)methane, isophorone diamine, paraxylylenediamine, and the like. As a diamine having a polypropyleneoxy chain, it is also possible to use JEFFAMINE (trade name, manufactured by Huntsman International LLC.).

As the dicarboxylic acid component, the component described as the dicarboxylic acid component in the section of the polyester is preferably applied.

Polymer Having Imide Bond

Examples of a polymer having an imide bond include polyimide, and the polyimide can be synthesized by a condensation reaction between a corresponding dicarboxylic acid anhydride and a diamine.

Specific examples of tetracarboxylic dianhydrides include 3,3′,4,4′-biphenyltetracarboxylic dianhydride (s-BPDA) and pyromellitic dianhydride (PMDA) and additionally include 2,3,3′,4′-biphenyltetracarboxylic dianhydride (a-BPDA), oxydiphthalic dianhydride, diphenylsulfone-3,4,3′,4′-tetracarboxylic dianhydride, bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenonetetracarboxylic dianhydride, 3,3′,4,4′-benzophenonetetracarboxylic dianhydride, bis(3,4-dicarboxyphenyl)methane dianhydride, 2,2-bis(3,4-dicarboxyphenyl)propane dianhydride, p-phenylene bis(trimellitic acid monoester anhydride), p-biphenylene bis(trimellitic acid monoester anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride, 2,3,6,7-naphthalenetetracarboxylic dianhydride, 1,4,5,8-naphthalene tetracarboxylic dianhydride, 4,4′-(2,2-hexafluoroisopropylidene)diphthalic dianhydride, 1,2,4,5-cyclohexane tetracarboxylic dianhydride, and the like. These dianhydrides can be used singly or two or more dianhydrides can also be used in a mixture form.

The tetracarboxylic acid component preferably includes at least s-BPDA and/or PMDA. For example, the content of s-BPDA in 100 mol % of the tetracarboxylic acid component is preferably 50 mol % or more, more preferably 70 mol % or more, and still more preferably 75 mol % or more. Tetracarboxylic dianhydrides desirably function as hard segment and thus preferably have a rigid benzene ring.

Specific examples of diamines being used in the polyimide include

1) diamines having one benzene nucleus such as paraphenylenediamine (1,4-diaminobenzene; PPD), 1,3-diaminobenzene, 2,4-toluenediamine, 2,5-toluenediamine, and 2,6-toluenediamine,

2) diaminodiphenyl ethers such as 4,4′-diaminodiphenyl ether, 3,3′-diaminodiphenyl ether, and 3,4′-diaminodiphenyl ether, diamines having two benzene nuclei such as 4,4′-diaminodiphenylmethane, 3,3′-dimethyl-4,4′-diaminobiphenyl, 2,2′-dimethyl-4,4′-diaminobiphenyl, 2,2′-bis(trifluoromethyl)-4,4′-diaminobiphenyl, 3,3′-dimethyl-4,4′-diaminodiphenylmethane, 3,3′-dicarboxy-4,4′-diaminodiphenylmethane, 3.3′,5,5′-tetramethyl-4,4′-diaminodiphenylmethane, bis(4-aminophenyl) sulfide, 4,4′-diaminobenzanilide, 3,3′-dichlorobenzidine, 3,3′-dimethylbenzidine, 2,2′-dimethylbenzidine, 3,3′-dimethoxybenzidine, 2,2′-dimethoxybenzidine, 3,3′-diaminodiphenyl ether, 3,4′-diaminodiphenyl ether, 4,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3,3′-diaminobenzophenone, 3,3′-diamino-4,4′-dichlorobenzophenone, 3,3′-diamino-4,4′-dimethoxybenzophenone, 3,3′-diaminodiphenylmethane, 3,4′-diaminodiphenylmethane, 4,4′-diaminodiphenylmethane, 2,2-bis(3-aminophenyl) propane, 2,2-bis(4-aminophenyl) propane, 2,2-bis(3-aminophenyl)-1,1, 1,3,3,3-hexafluoropropane, 2,2-bis(4-aminophenyl)-1,1, 1,3,3,3-hexafluoropropane, 3,3′-diaminodiphenyl sulfoxide, 3,4′-diaminodiphenyl sulfoxide, and 4,4′-diaminodiphenyl sulfoxide,

3) diamines having three benzene nuclei such as 1,3-bis(3-aminophenyl)benzene, 1,3-bis(4-aminophenyl)benzene, 1,4-bis(3-aminophenyl)benzene, 1,4-bis (4-aminophenyl)benzene, 1,3-bis(4-aminophenoxy)benzene, 1,4-bis(3-aminophenoxy)benzene, 1,4-bis(4-aminophenoxy)benzene, 1,3-bis(3-aminophenoxy)-4-trifluoromethylbenzene, 3,3′-diamino-4-(4-phenyl)phenoxybenzophenone, 3,3′-diamino-4,4′-di(4-phenylphenoxy)benzophenone, 1,3-bis(3-aminophenyl sulfide)benzene, 1,3-bis(4-aminophenyl sulfide)benzene, 1,4-bis(4-aminophenyl sulfide)benzene, 1,3-bis(3-aminophenylsulfone)benzene, 1,3-bis(4-aminophenylsulfone)benzene, 1,4-bis(4-aminophenylsulfone)benzene, 1,3-bis[2-(4-aminophenyl)isopropyl]benzene, 1,4-bis[2-(3-aminophenyl)isopropyl]benzene, and 1,4-bis[2-(4-aminophenyl)isopropyl]benzene,

4) diamines having four benzene nuclei such as 3,3′-bis(3-aminophenoxy)biphenyl, 3,3′-bis(4-aminophenoxy)biphenyl, 4,4′-bis(3-aminophenoxy)biphenyl, 4,4′-bis(4-aminophenoxy)biphenyl, bis[3-(3-aminophenoxy)phenyl]ether, bis[3-(4-aminophenoxy)phenyl]ether, bis[4-(3-aminophenoxy)phenyl]ether, bis[4-(4-aminophenoxy)phenyl]ether, bis[3-(3-aminophenoxy)phenyl]ketone, bis[3-(4-aminophenoxy)phenyl]ketone, bis[4-(3-aminophenoxy)phenyl]ketone, bis[4-(4-aminophenoxy)phenyl]ketone, bis[3-(3-aminophenoxy)phenyl]sulfide, bis[3-(4-aminophenoxy)phenyl]sulfide, bis[4-(3-aminophenoxy)phenyl]sulfide, bis[4-(4-aminophenoxy)phenyl]sulfide, bis[3-(3-aminophenoxy)phenyl]sulfone, bis[3-(4-aminophenoxy)phenyl]sulfone, bis[4-(3-aminophenoxy)phenyl]sulfone, bis[4-(4-aminophenoxy)phenyl]sulfone, bis[3-(3-aminophenoxy)phenyl]methane, bis[3-(4-aminophenoxy)phenyl]methane, bis[4-(3-aminophenoxy)phenyl]methane, bis[4-(4-aminophenoxy)phenyl]methane, 2,2-bis[3-(3-aminophenoxy)phenyl]propane, 2,2-bis[3-(4-aminophenoxy)phenyl]propane, 2,2-bis[4-(3-aminophenoxy)phenyl]propane, 2,2-bis[4-(4-aminophenoxy)phenyl]propane, 2,2-bis[3-(3-aminophenoxy)phenyl]-1,1,1,3,3,3-hexafluoropropane, 2,2-bis[3-(4-aminophenoxy)phenyl]-1,1,1,3,3,3-hexafluoropropane, 2,2-bis[4-(3-aminophenoxy)phenyl]-1,1,1,3,3,3-hexafluoropropane, and 2,2-bis[4-(4-aminophenoxy)phenyl]-1,1,1,3,3,3-hexafluoropropane.

These diamines can be used singly or two or more diamines can also be used in a mixture form. Diamines being used can be appropriately selected depending on desired characteristics and the like.

Polymer Having Urethane Bond

Examples of a polymer having an urethane bond include polyurethane, and the polyurethane can be synthesized by a condensation reaction between a corresponding diisocyanate and a diol.

Diisocyanate Compound

A diisocyanate compound is not particularly limited and can be appropriately selected, and examples thereof include compounds represented by Formula (M1) below and the like.

OCN—R^{M1}—NCO (M1)

In Formula (M1), R^{M1} represents a divalent aliphatic group or an aromatic hydrocarbon which may have a substituent (for example, preferably an alkyl group, an aralkyl group, an aryl group, an alkoxy group, or a halogen atom). R^{M1} may have an additional functional group that does not react with an isocyanate group, for example, any one of an ester group (a group having an ester bond such as an acyloxy group, an alkoxycarbonyl group, or an aryloxycarbonyl group), an urethane group, an amide group, and an ureido group as necessary.

The diisocyanate compound represented by Formula (M1) is not particularly limited, and examples thereof include products and the like being obtained by causing an addition reaction among diisocyanate, a triisocyanate compound (the compound described in Paragraphs 0034, 0035, and the like of JP2005-250438A), and one equivalent of a monofunctional alcohol or monofunctional amine compound having an ethylenic unsaturated group (the compound described in Paragraphs 0037 to 0040 and the like of JP2005-250438A).

The diisocyanate compound represented by Formula (M1) is not particularly limited and can be appropriately selected depending on the purposes. Meanwhile, a group represented by Formula (M2) below is preferably included.

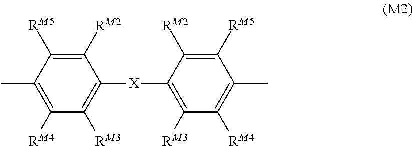

In Formula (M2), X represents a single bond, —CH₂—, —C(CH₃)₂—, —SO₂—, —S—, —CO—, or —O—. From the viewpoint of bonding properties, —CH₂— or —O— is preferred, and —CH₂— is more preferred. The above-described alkylene group exemplified here may also be substituted with a halogen atom (preferably a fluorine atom).

R^{M2} to R^{M5} each independently represent a hydrogen atom, a monovalent organic group, a halogen atom, —OR^{M6}, —N(R^{M6})₂, or —SR^{M6}. R^{M6} represents a hydrogen atom or a monovalent organic group.

Examples of the monovalent organic group include an alkyl group having 1 to 20 carbon atoms, an alkenyl group having 1 to 20 carbon atoms, —OR⁷ [here, R^{M7} represents a monovalent organic group (preferably an alkyl group having 1 to 20 carbon atoms, an aryl group having 6 to 10 carbon atoms, or the like)], an alkylamino group (the number of carbon atoms is preferably 1 to 20 and more preferably 1 to 6), an arylamino group (the number of carbon atoms is preferably 6 to 40 and more preferably 6 to 20), and the like.

R^{M2} to R^{M5} are preferably hydrogen atoms, alkyl groups having 1 to 20 carbon atoms, or —OR^{M7}, more preferably hydrogen atoms or alkyl groups having 1 to 20 carbon atoms, and still more preferably hydrogen atoms. Examples of the halogen atom include a fluorine atom, a chlorine atom, and a bromine atom.

The diisocyanate compound represented by Formula (M1) more preferably includes a group represented by Formula (M3) below.

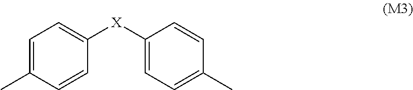

In Formula (M3), X is the same as X in Formula (M2), and a preferred range thereof is also identical.

The compositional fraction of the aromatic group represented by Formulae (M1) to (M3) in the polymer is preferably 10 mol % or more, more preferably 10 mol % to 50 mol %, and still more preferably 30 mol % to 50 mol %.

The diisocyanate compound represented by Formula (M1) are not particularly limited and can be appropriately selected depending on the purposes. Examples thereof include aromatic diisocyanate compounds such as 2,4-tolylene diisocyanate, dimers of 2,4-tolylene diisocyanate, 2,6-tolylene diisocyanate, p-xylylene diisocyanate, m-xylylene diisocyanate, 4,4′-diphenylmethane diisocyanate (MDI), 1,5-naphthylene diisocyanate, and 3,3′-dimethylbiphenyl-4,4′-diisocyanate; aliphatic diisocyanate compounds such as hexamethylene diisocyanate, trimethylhexamethylene diisocyanate, lysine diisocyanate, and dimer acid diisocyanate; alicyclic diisocyanate compounds such as isophorone diisocyanate, 4,4′-methylene bis(cyclohexyl isocyanate), methylcyclohexane-2.4 (or 2,6) diisocyanate, and 1,3-(isocyanatomethyl) cyclohexane; diisocyanate compounds which are reaction products between a diol and a diisocyanate such as adduct of one mole of 1,3-butylene glycol and two moles of tolylene diisocyanate; and the like. These diisocyanate compounds may be used singly or two or more diisocyanate compounds may be jointly used. Among these, 4,4′-diphenylmethane diisocyanate (MDI) is preferred.

As the diol component, the component described as the diol component in the section of the polyester is preferably applied.

Polymer Having Carbonate Bond

Examples of a polymer having a carbonate bond include polycarbonate, and the polycarbonate can be synthesized by means of interfacial polycondensation of a diol such as bisphenol A and carbonyl chloride in the presence of an alkali catalyst. In addition, the polycarbonate can be synthesized by means of an ester exchange reaction between bisphenol A and diphenyl carbonate.

As the diol component, the component described as the diol component in the section of the polyester is preferably applied.

In addition, it is also possible to use diol components which are ordinarily commercially available, contain polycarbonate bonds in molecular chains, and have reactive groups in the terminals, and examples thereof include DURANOL series (manufactured by Asahi Kasei Corporation), ETERNACOLL series (manufactured by Ube Industries, Ltd.), PLACCEL CD series (manufactured by Daicel Corporation), and KURARAY POLYOL C series (manufactured by Kuraray Co., Ltd.) all of which are trade names.

Polymer Having Urea Bond

Examples of a polymer having an urea bond include polyurea, and the polyurea can be synthesized by means of polycondensation of a corresponding diisocyanate compound and a diamine compound in the presence of an amine catalyst.

As the diisocyanate compound, the component described as the diisocyanate compound in the section of the polyurethane is preferably applied, and, as the diamine compound, the component described as the diamine compound in the section of the polyimide is preferably applied.

Polymer Having Ether Bond

Examples of a polymer having an ether bond include polyether, and the polyether can be synthesized by means of ring-opening polymerization of a cyclic ether compound.

In addition, it is also possible to use polyesters which are ordinarily commercially available, contain polyester bonds in molecular chains, and have reactive groups in the terminals.

Examples of the cyclic ether compound include ethylene oxide, trimethylene oxide, propylene oxide, isobutylene oxide, 2,3-butylene oxide, 1,2-epoxyheptane, 1,2-epoxyhexane, glycidyl methyl ether, 1,7-octadiene diepoxide, oxetane, tetrahydrofuran, tetrahydropyran, and the like.

Polymer Having Sulfide Bond

Examples of a polymer having a sulfide bond include polysulfide, and the polysulfide can be synthesized by means of polycondensation between a dihalide and an alkali metal salt of a polysulfide ion.

In addition, it is also possible to use polysulfides which are ordinarily commercially available, has a polysulfide structure in molecular chains, and have reactive groups in the terminals.

Meanwhile, the polymer having the carbon-carbon unsaturated bonds not contributing to aromaticity in the main chain can be obtained by changing the respective monomers described above into monomers having the carbon-carbon unsaturated bonds not contributing to aromaticity.

As commercially available raw materials, it is possible to use, for example, appropriate combinations of the following materials. However, the present invention is not limited thereto.

Dicarboxylic Acid or Dicarboxylic Acid Chloride Compound Having Carbon-Carbon Unsaturated Bonds not Contributing to Aromaticity

As a dicarboxylic acid or a dicarboxylic acid chloride compound having carbon-carbon unsaturated bonds not contributing to aromaticity, it is possible to preferably use fumaric acid, maleic acid, citraconic acid, mesaconic acid, trans, trans-muconic acid, dihydromuconic acid, acetylene dicarboxylic acid, and the like.

Carboxylic acid chlorides can be easily obtained by forming an acid chloride of the above-described carboxylic acid using a thionyl chloride.

Dicarboxylic Anhydride Having Carbon-Carbon Unsaturated Bonds not Contributing to Aromaticity

As a dicarboxylic anhydride having carbon-carbon unsaturated bonds not contributing to aromaticity, it is possible to preferably use bicyclo[2.2.2]octo-7-ene-2,3,5,6-tetracarboxylic dianhydride, 5-(2,5-dioxotetrahydrofuryl)-3-methyl-3-cyclohexene-1,2-dicarboxylic anhydride, and the like.

Diamine Compound Having Carbon-Carbon Unsaturated Bonds not Contributing to Aromaticity

A diamine compound having carbon-carbon unsaturated bonds not contributing to aromaticity can be obtained by forming a primary amine of a dihalogen compound having carbon-carbon unsaturated bonds not contributing to aromaticity by means of Gabriel's synthesis.

The Gabriel's synthesis refers to a method in which N-alkyl phthalimide being obtained by a reaction between potassium phthalimide and an alkyl halide is decomposed by hydrazine, thereby obtaining a primary amine.

Examples of the dihalogen compound having carbon-carbon unsaturated bonds from which a diamine compound having carbon-carbon unsaturated bonds can be derived include trans-1,4-dibromo-2-butene, cis-1,4-dibromo-2-butene, trans, trans-1,6-dibromo-2,4-hexadiene or 1,4-dichloro-2-butyne, and 1,6-dichloro-2,4-hexadiyne.

Diol Compound Having Carbon-Carbon Unsaturated Bonds not Contributing to Aromaticity

As a short-chain diol compound having carbon-carbon unsaturated bonds not contributing to aromaticity, it is possible to preferably use cis-2-butene-1,4-diol, trans-2-butene-1,4-diol, 2-butyne-1,4-diol, 2,5-dimethyl-3-hexyne-2,5-diol, 3-hexyne-2,5-diol, 3,6-dimethyl-4-octyne-3,6-diol, 1,4-bis(2-hydroxyethoxy)-2-butyne, 2,4,7,9-tetramethyl-5-decyne-4,7-diol, 2,4-hexadiyne-1,6-diol, cis-2-heptene-3-hydroxymethyl-1-ol, 1-cyclohexene-2,5,5-trimethyl-1,3-diol, and the like.

Regarding a long-chain diol compound having carbon-carbon unsaturated bonds not contributing to aromaticity, as terminal alcohol-modified diols of polybutadiene, it is possible to preferably use NISSO-PB G1000 (manufactured by Nippon Soda Co., Ltd.), NISSO-PB G2000 (manufactured by Nippon Soda Co., Ltd.), NISSO-PB G3000 (manufactured by Nippon Soda Co., Ltd.), Krasol LBH 2000 (manufactured by Clay Valley), Krasol LBH-P2000 (manufactured by Clay Valley), Krasol LBH 3000 (manufactured by Clay Valley), Krasol LBH-P3000 (manufactured by Clay Valley), Polybd R-45HT (manufactured by Idemitsu Kosan Co., Ltd.), Polybd R-15HT (manufactured by Idemitsu Kosan Co., Ltd.), and the like all of which are trade names, and, as terminal alcohol-modified diol of polyisoprene, it is possible to preferably use Polyip (trade name, manufactured by Idemitsu Kosan Co., Ltd.), and the like.

The polymer being used in the present invention also preferably contains at least one functional group (1) selected from the following group of functional groups (1).

Groups being included in the group of functional groups (I) represent a carboxy group, a sulfonic acid group, a phosphoric acid group, a hydroxy group, —CONR^{NA}₂, a cyano group, NR^{NA}₂, a mercapto group, an epoxy group, or a (meth)acryl group [that is, (meth)acryloyl group]. Here, R^{NA} represents a hydrogen atom, an alkyl group (the number of carbon atoms is preferably 1 to 12, more preferably 1 to 6, and still more preferably 1 to 3), or an aryl group (the number of carbon atoms is preferably 6 to 22, more preferably 6 to 14, and still more preferably 6 to 10).

The functional group (I) selected from the group of functional groups (I) may be one group or two or more groups selected from the above-described group.

Meanwhile, when the sulfonic acid group and the phosphoric acid group are ester bodies, groups constituting esters are preferably alkyl groups (the number of carbon atoms is preferably 1 to 12, more preferably 1 to 6, and still more preferably 1 to 3), alkenyl groups (the number of carbon atoms is preferably 2 to 12 and more preferably 2 to 6), alkynyl groups (the number of carbon atoms is preferably 2 to 12 and more preferably 2 to 6), aryl groups (the number of carbon atoms is preferably 6 to 22, more preferably 6 to 14, and still more preferably 6 to 10), or aralkyl groups (the number of carbon atoms is preferably 7 to 23, more preferably 7 to 15, and still more preferably 7 to 11), and more preferably alkyl groups. Meanwhile, the carboxy group, the sulfonic acid group, and the phosphoric acid group may form a salt with an arbitrary counter ion. Examples of the counter ion include alkali metal cations, quaternary ammonium cations, and the like.

The functional group (I) is more preferably selected from a carboxy group, a sulfonic acid group, a phosphoric acid group, a hydroxy group, or a (meth)acryl group and still more preferably selected from a carboxy group, a hydroxy group, or a (meth)acryl group.

Examples of the method for introducing the functional group (I) include a method in which a monomer containing the functional group (I) is copolymerized with the polymer during the polymerization of the polymer being used in the present invention. Alternatively, the functional group (I) may be introduced into the polymer terminal by polymerizing a polymerization initiator or chain transfer agent containing the functional group (I) with the polymer or the functional group (I) may be introduced into the side chain or terminal by means of a polymer reaction. In addition, commercially available functional group-introducing resins may be used (for example, “KYNAR (registered trademark) ADX series”) (trade mark, manufactured by Arkema) and the like.

Another preferred aspect of the polymer being used in the present invention is an aspect in which atoms (preferably carbon atoms) constituting the main chain are substituted with a group selected from alkyl groups (for example, methyl and trifluoromethyl), alkenyl groups (for example, vinyl and 2-propenyl), and carboxy groups.

Here, the polymer being used in the present invention may be any one of a block copolymer, an alternate copolymer, and a random copolymer.

That is, a structural unit having carbon-carbon unsaturated bonds not contributing to aromaticity may form a block structure or may form an alternate copolymer or a random copolymer with another structural unit.

In addition, in a case in which the sulfide-based solid electrolyte is used, the water content of the polymer is preferably 100 ppm or less from the viewpoint of suppressing the generation of hydrogen sulfide attributed to a reaction between the sulfide-based solid electrolyte and water and a decrease in the ion conductivity.

The water content is computed by using a polymer which has been dried in a vacuum at 80° C. as a specimen, measuring the amount (g) of moisture in the specimen using a Karl Fischer liquid AQUAMICRON AX (trade name, manufactured by Mitsubishi Chemical Corp.) and the Karl Fischer method, and dividing the measured amount (g) of moisture by the mass (g) of the specimen.

The glass transition temperature (Tg) of the polymer being used in the present invention is preferably lower than 50° C. more preferably −100° C. or higher and lower than 50° C., more preferably −80° C. or higher and lower than 30° C., and particularly preferably −80° C. or higher and lower than 0° C. When the glass transition temperature is in the above-described range, a favorable ion conductivity can be obtained.

The glass transition temperature is measured using a dried specimen and a differential scanning calorimeter “X-DSC7000” (trade name, SII•NanoTechnology Inc.) under the following conditions. The glass transition temperature of the same specimen is measured twice, and the measurement result of the second measurement is used.

Atmosphere of the measurement chamber: nitrogen (50 mL/min)

Temperature-increase rate: 5° C./min

Measurement-start temperature: −100° C.

Measurement-end temperature: 200° C.

Specimen plate: aluminum plate

Mass of the measurement specimen: 5 mg

Estimation of Tg: Tg is estimated by rounding off the middle temperature between the declination-start point and the declination-end point in the DSC chart to the integer.

The mass average molecular weight of the polymer being used in the present invention is preferably 10,000 or more and less than 500,000, more preferably 15,000 or more and less than 200,000, and still more preferably 15,000 or more and less than 150,000.

When the mass average molecular weight of the polymer is in the above-described range, more favorable bonding properties develop, and handling properties (manufacturing suitability) become favorable.

As the mass average molecular weight of the polymer being used in the present invention, a value measured by means of the following standard specimen conversion using gel permeation chromatography (GPC) is used. Regarding a measurement instrument and measurement conditions, the following conditions 1 are considered as the basic conditions, and the conditions 2 can be used depending on the solubility and the like of the specimen. However, depending on the kind of the polymer, a more appropriate and proper carrier (eluent) and a column suitable to the above-described carrier may be selected and used.

(Conditions 1)

Measurement instrument: EcoSEC HLC-8320 (trade name, manufactured by Tosoh Corporation)

Column: Two columns of TOSOH TSKgel Super AWM-H (trade name, manufactured by Tosoh Corporation) are connected

Carrier: 10 mM LiBr/N-methylpyrrolidone

Measurement temperature: 40° C.

Carrier flow rate: 1.0 ml/min

Specimen concentration: 0.1 mass %

Detector: RI (refractive index) detector

Standard specimen: Polystyrene

(Conditions 2)

Measurement instrument: Save as above

Column: A column obtained by connecting TOSOH TSKgel Super HZM-H,
TOSOH TSKgel Super HZ4000, and
TOSOH TSKgel Super HZ2000 (all are trade names, manufactured by Tosoh Corporation) is used

Carrier: Tetrahydrofuran

Measurement temperature: 40° C.

Carrier flow rate: 1.0 ml/min

Specimen concentration: 0.1 mass %

Detector: RI (refractive index) detector

Standard specimen: Polystyrene

Meanwhile, the electrolytic crosslinking polymer after electrolytic polymerization (hereinafter, also referred to simply as the electrolytic crosslinked body) forms a crosslinking structure, and it is difficult to measure the molecular weight without dissolving the polymer in the eluent. Meanwhile, the mass average molecular weight measured in a state in which component insoluble in the eluent have been removed is 200,000 to 1,000,000.

Specific examples of the polymer being used in the present invention will be illustrated below. Meanwhile, the present invention is not interpreted to be limited by the specific examples.

Meanwhile, numerical values in the compounds represent the molar fractions of the structural units in parentheses, and x, y, and z in the compounds are arbitrary integers of 0 or more and represent the molar fractions of the structural units in parentheses. However, x+y is not zero. Here, as the polymer being used in the present invention, it is possible to preferably use a polymer in which x is 15 and y and z are five or a polymer in which x is 30 and y and z are 10. In addition, the respective polymers may be any one of a block copolymer, an alternate copolymer, and a random copolymer.

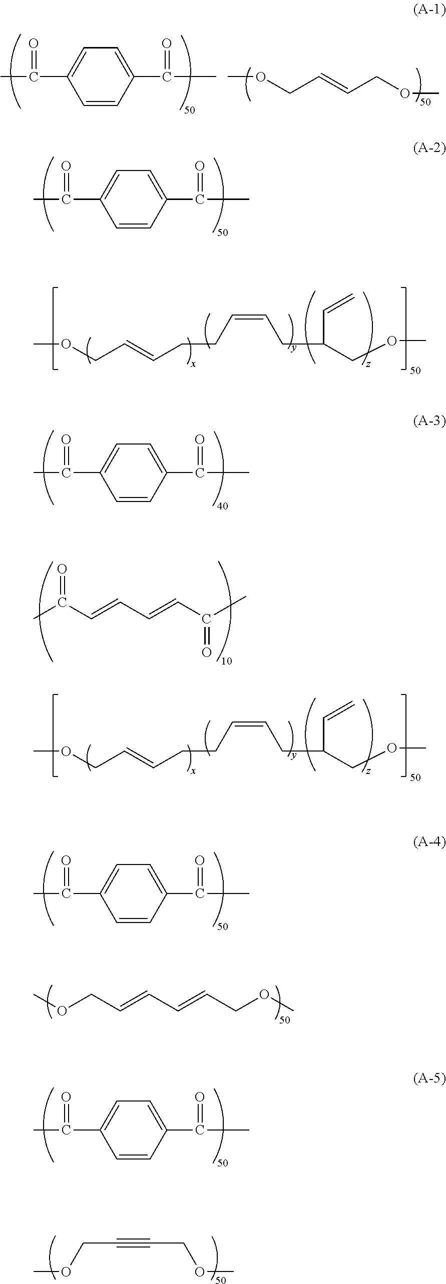

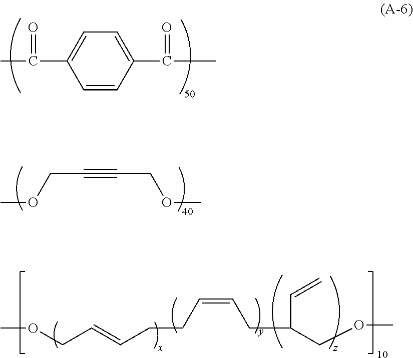

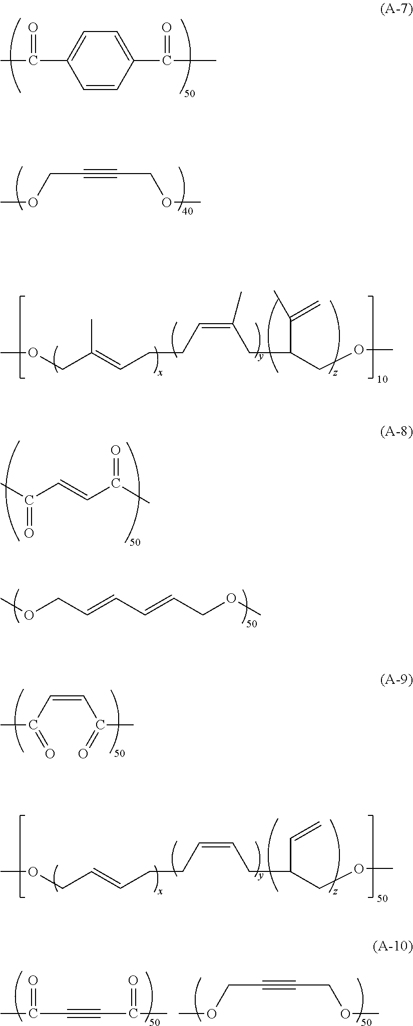

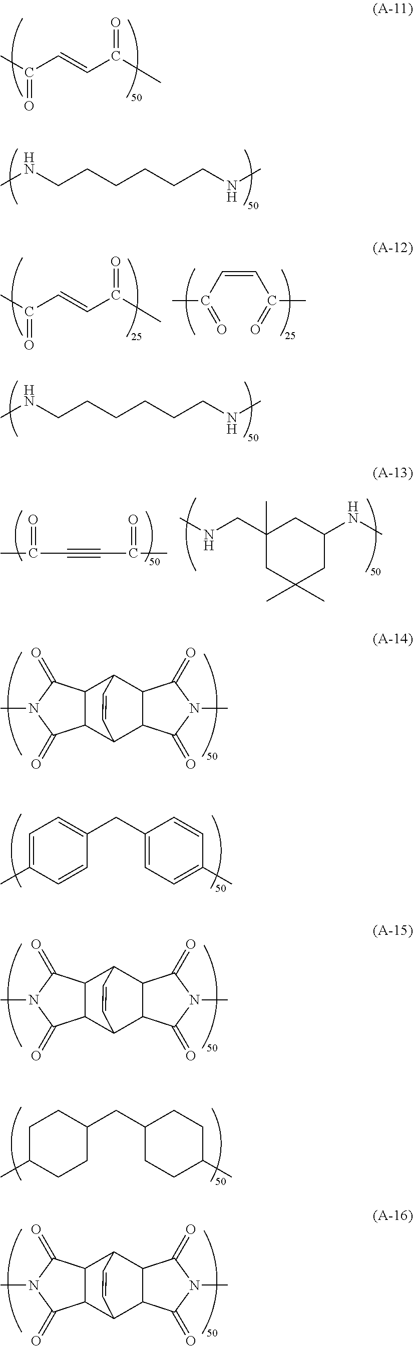

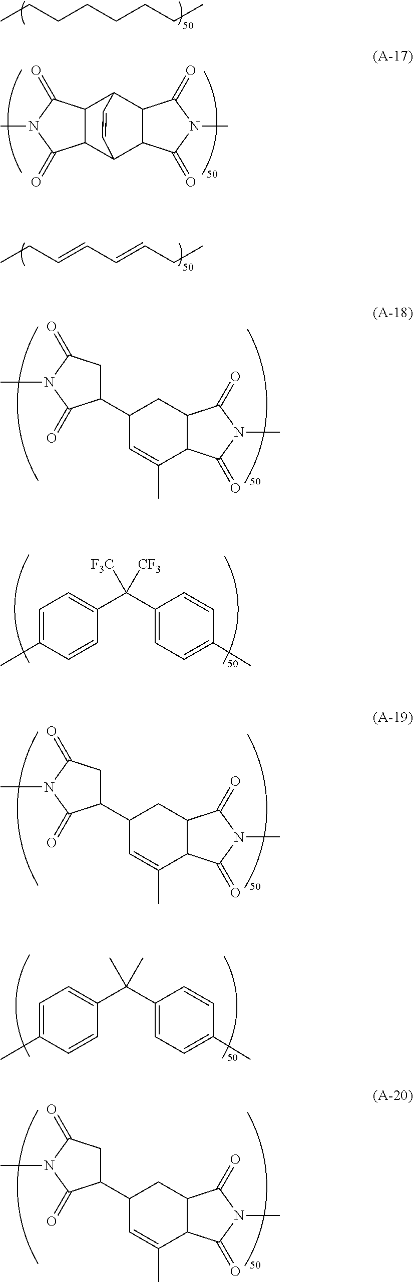

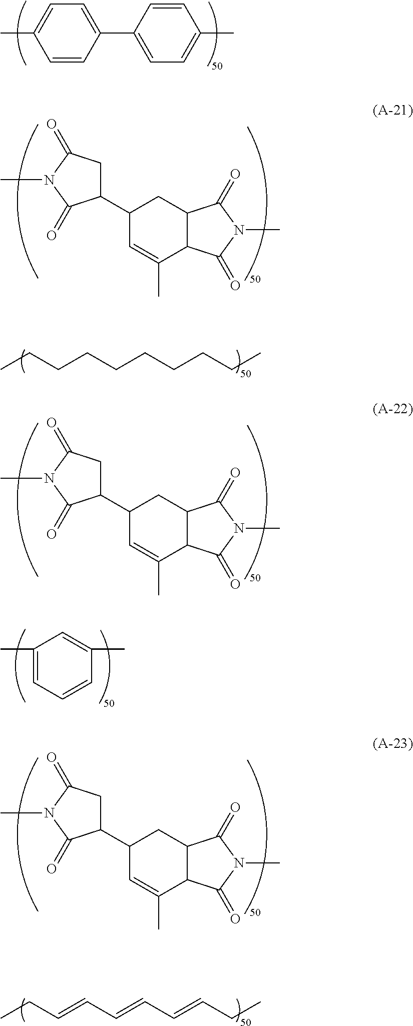

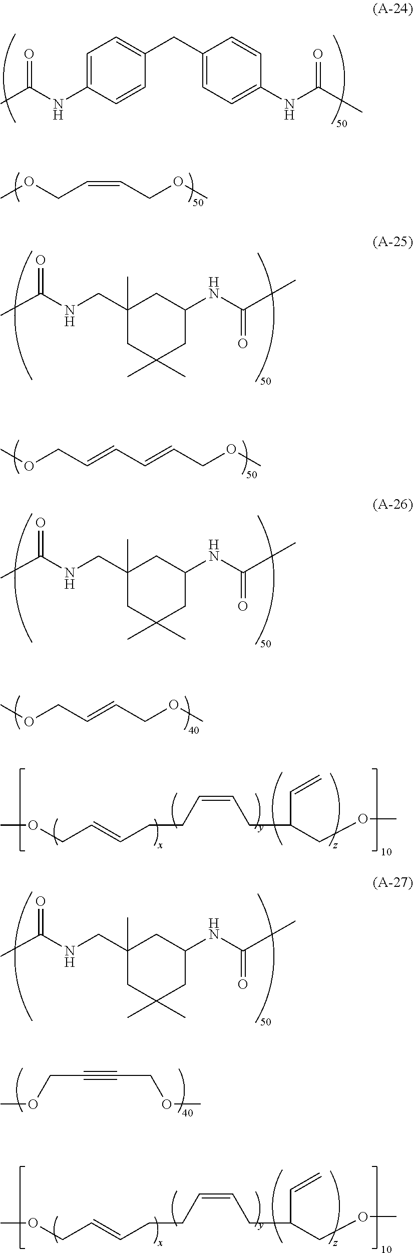

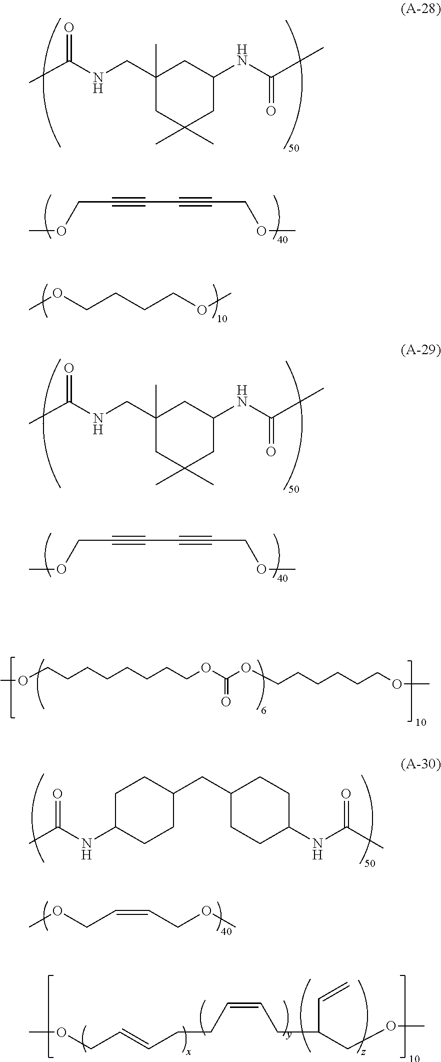

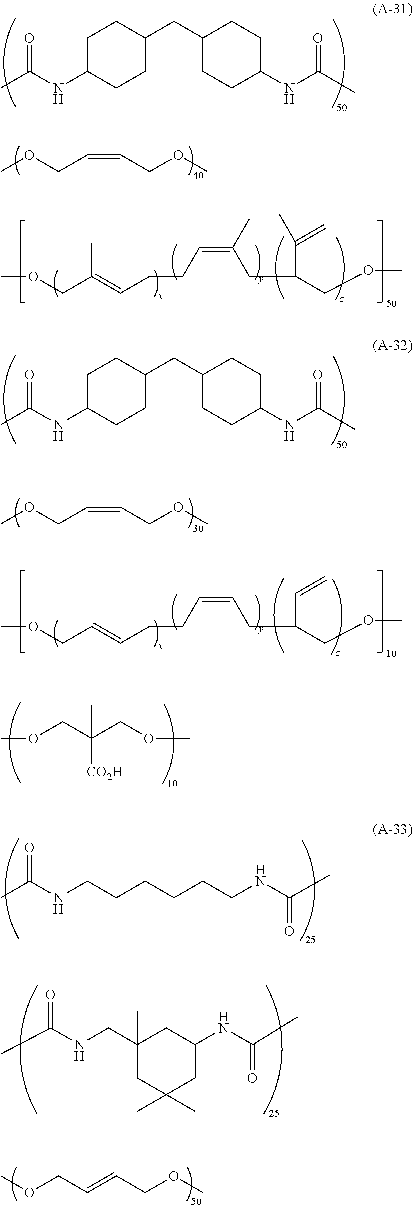

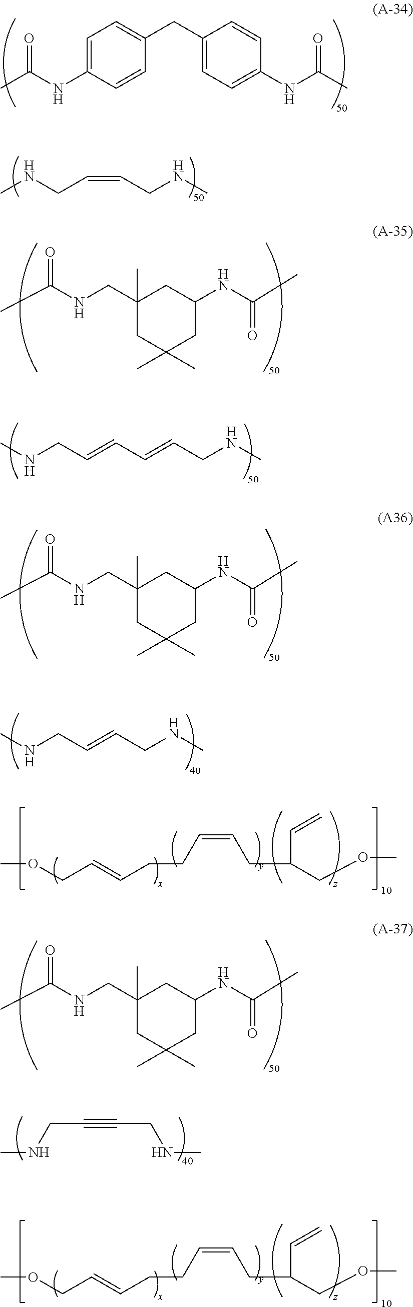

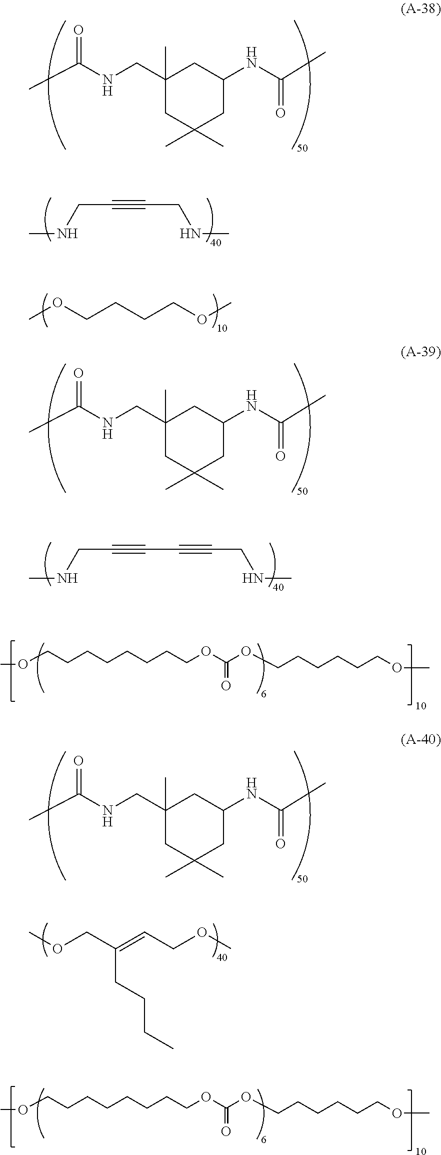

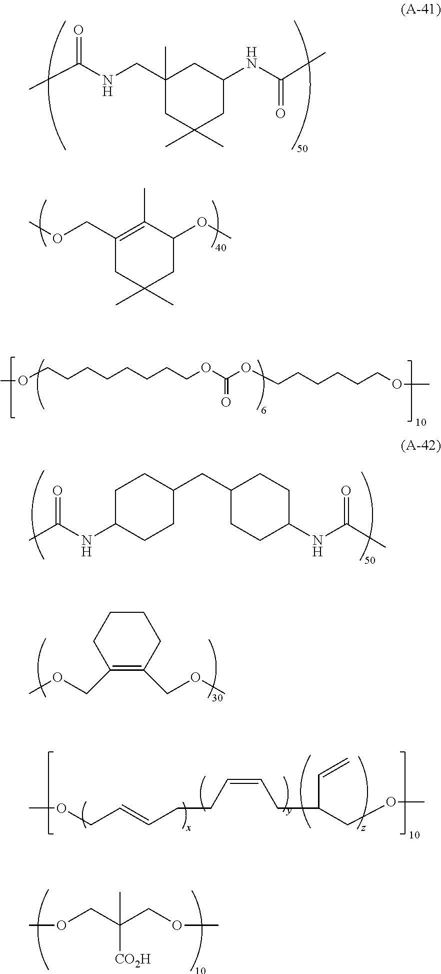

Here, the mass average molecular weights and the glass transition temperatures of Exemplary Compounds (A-1) to (A-42) are collectively shown in Table 1. Meanwhile, in the above-illustrated structures, x is 30 and y and z are 10.

TABLE 1

| | Mass average | Glass transition |
|---|---|---|
| No. | molecular weight | temperature (° C.) |
| A-1 | 76,300 | 58 |
| A-2 | 103,000 | −20 |
| A-3 | 129,400 | −32 |
| A-4 | 93,200 | 44 |
| A-5 | 63,100 | 76 |
| A-6 | 119,000 | 9 |
| A-7 | 137,600 | 0 |
| A-8 | 53,500 | 61 |
| A-9 | 58,900 | 20 |
| A-10 | 42,000 | 89 |
| A-11 | 87,000 | 93 |
| A-12 | 37,800 | 43 |
| A-13 | 54,500 | 32 |
| A-14 | 152,400 | 190 |
| A-15 | 132,500 | 210 |
| A-16 | 112,000 | 142 |
| A-17 | 87,000 | 169 |
| A-18 | 86,200 | 149 |
| A-19 | 63,400 | 172 |
| A-20 | 132,000 | 243 |
| A-21 | 163,100 | 222 |
| A-22 | 109,000 | 213 |
| A-23 | 87,600 | 153 |
| A-24 | 76,900 | 123 |
| A-25 | 43,600 | 96 |
| A-26 | 54,900 | 10 |
| A-27 | 44,700 | −10 |
| A-28 | 42,100 | 49 |
| A-29 | 37,600 | −3 |
| A-30 | 56,100 | −6 |
| A-31 | 31,900 | −33 |
| A-32 | 41,700 | 5 |
| A-33 | 53,100 | −8 |
| A-34 | 67,000 | 153 |
| A-35 | 32,400 | 80 |
| A-36 | 56,300 | −2 |
| A-37 | 74,300 | −6 |
| A-38 | 23,900 | 113 |
| A-39 | 49,600 | 47 |
| A-40 | 21,000 | 25 |
| A-41 | 19,800 | 67 |
| A-42 | 34,200 | 76 |

In the present specification, substituents which are not clearly expressed as substituted or unsubstituted (which is also true for linking groups) may have an arbitrary substituent in the groups unless particularly otherwise described. This is also true for compounds which are not clearly expressed as substituted or unsubstituted. Examples of preferred substituents include the following substituent T. In addition, in a case in which substituents are expressed simply as “substituent”, the substituent T is referred to.

Examples of the substituent T include the following substituents.

Alkyl groups (preferably alkyl groups having 1 to 20 carbon atoms, for example, methyl, ethyl, isopropyl, t-butyl, pentyl, heptyl, 1-ethylpentyl, benzyl, 2-ethoxyethyl, 1-carboxymethyl, and the like), alkenyl groups (preferably alkenyl groups having 2 to 20 carbon atoms, for example, vinyl, allyl, oleyl, and the like), alkynyl groups (preferably alkynyl groups having 2 to 20 carbon atoms, for example, ethynyl, butadiynyl, phenylethynyl, and the like), cycloalkyl groups (preferably cycloalkyl groups having 3 to 20 carbon atoms, for example, cyclopropyl, cyclopentyl, cyclohexyl, 4-methylcyclohexyl, and the like), aryl groups (preferably aryl groups having 6 to 26 carbon atoms, for example, phenyl, I-naphthyl, 4-methoxyphenyl, 2-chlorophenyl, 3-methylphenyl, and the like), heterocyclic groups (preferably heterocyclic groups having 2 to 20 carbon atoms, preferably heterocyclic groups of a five- or six-membered ring having at least one oxygen atom, sulfur atom, or nitrogen atom as the ring-constituting atom, for example, tetrahydropyranyl, tetrahydrofuranyl, 2-pyridyl, 4-pyridyl, 2-imidazolyl, 2-benzimidazolyl, 2-thiazolyl, 2-oxazolyl, and the like),

alkoxy groups (preferably alkoxy groups having 1 to 20 carbon atoms, for example, methoxy, ethoxy, isopropyloxy, benzyloxy, and the like), alkenyloxy groups (preferably alkenyloxy groups having 2 to 20 carbon atoms, for example, vinyloxy, allyloxy, oleyloxy, and the like), alkynyloxy groups (preferably alkynyloxy groups having 2 to 20 carbon atoms, for example, ethynyloxy, phenylethynyloxy, and the like), cycloalkyloxy groups (preferably cycloalkyloxy groups having 3 to 20 carbon atoms, for example, cyclopropyloxy, cyclopentyloxy, cyclohexyloxy, 4-methylcyclohexyloxy, and the like), aryloxy groups (preferably aryloxy groups having 6 to 26 carbon atoms, for example, phenoxy, 1-naphthyloxy, 3-methylphenoxy, 4-methoxyphenoxy, and the like), alkoxycarbonyl groups (preferably alkoxycarbonyl groups having 2 to 20 carbon atoms, for example, ethoxycarbonyl, 2-ethylhexyloxycarbonyl, and the like), aryloxycarbonyl groups (preferably aryloxycarbonyl groups having 7 to 26 carbon atoms, for example, phenoxycarbonyl, 1-naphthyloxycarbonyl, 3-methylphenoxycarbonyl, 4-methoxyphenoxycarbonyl, and the like), amino groups (preferably amino groups having 0 to 20 carbon atoms, including an alkylamino group, an alkenylamino group, an alkynylamino group, an arylamino group, and a heterocyclic amino group, for example, amino, N,N-dimethylamino, N,N-diethylamino, N-ethylamino, N-allylamino, N-ethynylamino, anilino, 4-pyridylamino, and the like), sulfamoyl groups (preferably sulfamoyl groups having 0 to 20 carbon atoms, for example, N,N-dimethylsulfamoyl, N-phenylsulfamoyl, and the like), acyl groups (including an alkanoyl group, an alkenoyl group, an alkynoyl group, a cycloalkanoyl group, an aryloyl group, and a heterocyclic carbonyl group, preferably acyl groups having 1 to 23 carbon atoms, for example, formyl, acetyl, propionyl, butyryl, pivaloyl, stearoyl, acryloyl, methacryloyl, crotonoyl, oleoyl, propioloyl, cyclopropanoyl, cyclopentanoyl, cyclohexanoyl, benzoyl, nicotinoyl, isonicotinoyl, and the like), acyloxy groups (including an alkanoyloxy group, an alkenoyloxy group, an alkynoyloxy group, a cycloalkanoyloxy group, an aryloyloxy group, and a heterocyclic carbonyloxy group, preferably acyloxy groups having 1 to 23 carbon atoms, for example, formyloxy, acetyloxy, propionyloxy, butyryloxy, pivaloyloxy, stearoyloxy, acryloyloxy, methacryloyloxy, crotonoyloxy, oleoyloxy, propioloyloxy, cyclopropanoyloxy, cyclopentanoyloxy, cyclohexanoyloxy, nicotinoyloxy, isonicotinoyloxy, and the like),

carbamoyl groups (preferably carbamoyl groups having 1 to 20 carbon atoms, for example, N,N-dimethylcarbamoyl, N-phenylcarbamoyl, and the like), acylamino groups (preferably acylamino groups having 1 to 20 carbon atoms, for example, acetylamino, acryloylamino, methacryloylamino, benzoylamino, and the like), sulfonamido groups (including an alkylsulfonamido group and an arylsulfonamido group, preferably sulfonamido groups having 1 to 20 carbon atoms, for example, methanesulfonamido, benzenesulfonamido, and the like), alkylthio groups (preferably alkylthio groups having 1 to 20 carbon atoms, for example, methylthio, ethylthio, isopropylthio, benzylthio, and the like), arylthio groups (preferably arylthio groups having 6 to 26 carbon atoms, for example, phenylthio, I-naphthylthio, 3-methylphenylthio, 4-methoxyphenylthio, and the like), alkylsulfonyl groups (preferably alkylsulfonyl groups having 1 to 20 carbon atoms, for example, methylsulfonyl, ethylsulfonyl, and the like), arylsulfonyl groups (preferably arylsulfonyl groups having 6 to 22 carbon atoms, for example, benzenesulfonyl and the like), alkylsilyl groups (preferably alkylsilyl groups having 1 to 20 carbon atoms, for example, monomethylsilyl, dimethylsilyl, trimethylsilyl, triethylsilyl, benzyldimethylsilyl, and the like), arylsilyl groups (preferably arylsilyl groups having 6 to 42 carbon atoms, for example, triphenylsilyl, dimethylphenylsilyl, and the like), phosphoryl groups (preferably phosphoric acid groups having 0 to 20 carbon atoms, for example, —OP(═O)(R)₂), phosphonyl groups (preferably phosphonyl groups having 0 to 20 carbon atoms, for example, —P(═O)(R^{p})₂), phosphinyl groups (preferably phosphinyl groups having 0 to 20 carbon atoms, for example, —P(R^{P})₂), sulfo groups or salts thereof, a hydroxy group, a mercapto group, a cyano group, and halogen atoms (for example, a fluorine atom, a chlorine atom, a bromine atom, an iodine atom, and the like).

R^{P} is a hydrogen atom, a hydroxy group, or a substituent other than hydroxy. Examples of the substituent include the above-described substituent T, and an alkyl group (the number of carbon atoms is preferably 1 to 24, more preferably 1 to 12, still more preferably 1 to 6, and particularly preferably 1 to 3), an alkenyl group (the number of carbon atoms is preferably 2 to 24, more preferably 2 to 12, still more preferably 2 to 6, and particularly preferably 2 and 3), an alkynyl group (the number of carbon atoms is preferably 2 to 24, more preferably 2 to 12, still more preferably 2 to 6, and particularly preferably 2 and 3), an aralkyl group (the number of carbon atoms is preferably 7 to 22, more preferably 7 to 14, and particularly preferably 7 and 10), an aryl group (the number of carbon atoms is preferably 6 to 22, more preferably 6 to 14, and particularly preferably 6 to 10), an alkoxy group (the number of carbon atoms is preferably 1 to 24, more preferably 1 to 12, still more preferably 1 to 6, and particularly preferably 1 to 3), an alkenyloxy group (the number of carbon atoms is preferably 2 to 24, more preferably 2 to 12, still more preferably 2 to 6, and particularly preferably 2 and 3), an alkynyloxy group (the number of carbon atoms is preferably 2 to 24, more preferably 2 to 12, still more preferably 2 to 6, and particularly preferably 2 and 3), an aralkyloxy group (the number of carbon atoms is preferably 7 to 22, more preferably 7 to 14, and particularly preferably 7 to 10), and an aryloxy group (the number of carbon atoms is preferably 6 to 22, more preferably 6 to 14, and particularly preferably 6 to 10) are preferred.

Here, in the respective groups exemplified as the substituent T, the substituent T may be further substituted. Examples thereof include aralkyl groups in which an alkyl group is substituted with an aryl group and halogenated alkyl groups in which an alkyl group is substituted with a halogen atom.

The content of the electrolytic crosslinking polymer in the solid electrolyte composition is preferably 0.1 parts by mass or more, more preferably 0.3 parts by mass or more, and particularly preferably 1 part by mass or more with respect to 100 parts by mass of the inorganic solid electrolyte (including an active material in the case of being used). The upper limit is preferably 20 parts by mass or less, more preferably 10 parts by mass or less, and particularly preferably 5 parts by mass or less.

The content of the electrolytic crosslinking polymer in the solid content is preferably 0.1 parts by mass or more, more preferably 0.3 parts by mass or more, and particularly preferably 1 part by mass or more of the solid electrolyte composition. The upper limit is preferably 20 parts by mass or less, more preferably 10 parts by mass or less, and particularly preferably 5 parts by mass or less.

When the amount of the electrolytic crosslinking polymer being used is in the above-described range, it is possible to more effectively realize both of the bonding properties of the inorganic solid electrolyte and the properties of suppressing interface resistance.

Meanwhile, as a binder being applied to the present invention, not only binders made of a specific electrolytic crosslinking polymer described above but also other binders or combinations with a variety of additives may be used. The above-described amount blended is specified as the total amount of the electrolytic crosslinking polymer, but may be considered as the total amount of the binder.

(Lithium Salt)

In the all solid state secondary battery of the present invention, at least one layer of the positive electrode active material layer, the negative electrode active material layer, or the inorganic solid electrolyte layer also preferably further contains a lithium salt.

Lithium salts that can be used in the present invention are preferably lithium salts being ordinarily used in this kind of products and are not particularly limited, and preferred examples thereof include the following salts.

(L-1) Inorganic Lithium Salts

Examples thereof include the following compounds.

Inorganic fluoride salts such as LiPF₆. LiBF₄, LiAsF₆, and LiSbF₆

Perhalogen acids such as LiClO₄, LiBrO₄, and LiIO₄

Inorganic chloride salts such as LiAlCl₄

(L-2) Fluorine-Containing Organic Lithium Salts

Examples thereof include the following compounds.

Perfluoroalkanesulfonate salts such as LiCF₃SO₃

Perfluoroalkanesulfonylimide salts such as LiN(CF₃SO₂)₂, LiN(CF₃CF₂SO₂)₂, LiN(FSO₂)₂, LiN(CF₃SO₂)(C₄F₉)SO₂)

Perfluoroalkanesulfonyl methide salts such as LiC(CF₃SO₂)₃

Fluoroalkyl fluorophosphates salts such as Li[PF₃(CF₂CF₂CF₃)], Li[PF₄(CF₂CF₂CF₃)₂], Li[PF₃(CF₂CF₂CF₃)₃], Li[PF₅(CF₂CF₂CF₂CF₃)], Li[PF₄(CF₂CF₂CF₂CF₃)₂], and Li[PF₃(CF₂CF₂CF₂CF₃)₃]

(L-3) Oxalate Borate Salts

Examples thereof include the following compounds.

Lithium bis(oxalato)borate, lithium difluorooxalatoborate, and the like

Among these, LiPF₆, LiBF₄, LiAsF₆, LiSbF₆, LiClO₄, Li(Rf¹SO₃), LiN(Rf¹SO₂)₂, LiN(FSO₂)₂, and LiN(Rf¹SO₂)(Rf²SO₂) are preferred, and lithium imide salts such as LiPF₆, LiBF₄, LiN(Rf¹SO₂)₂, LiN(FSO₂)₂, and LiN(Rf¹SO₂)(Rf²SO₂) are more preferred. Here, Rf¹ and Rf² each independently represent a perfluoroalkyl group.

Among these, fluorine-containing organic lithium salts are preferred, perfluoroalkanesulfonylimide salts are more preferred, and symmetric-system perfluoroalkanesulfonylimide salts such as LiN(CF₃SO₂)₂ and LiN(CF₃CF₂SO₂)₂ are still more preferred.

Meanwhile, these lithium salts may be used singly or two or more lithium salts may be arbitrarily combined together.

The content of the lithium salt is preferably more than 0 parts by mass and more preferably 5 parts by mass or more with respect to 100 parts by mass of the solid electrolyte. The upper limit is preferably 50 parts by mass or less and more preferably 20 parts by mass or less.

(Dispersion Medium)

In the solid electrolyte composition of the present invention, a dispersion medium dispersing the respective components described above may be used. Examples of the dispersion medium include water-soluble organic media. Specific examples of the dispersion medium include the following media.

Examples of alcohol compound solvents include methyl alcohol, ethyl alcohol, 1-propyl alcohol, 2-propyl alcohol, 2-butanol, ethylene glycol, propylene glycol, glycerin, 1,6-hexanediol, cyclohexanediol, sorbitol, xylitol, 2-methyl-2,4-pentanediol, 1,3-butanediol, and 1,4-butanediol.

Examples of ether compound solvents include alkylene glycol alkyl ethers (ethylene glycol monomethyl ether, ethylene glycol monobutyl ether, diethylene glycol, dipropylene glycol, propylene glycol monomethyl ether, diethylene glycol monomethyl ether, triethylene glycol, polyethylene glycol, propylene glycol monomethyl ether, dipropylene glycol monomethyl ether, tripropylene glycol monomethyl ether, diethylene glycol monobutyl ether, diethylene glycol monobutyl ether, and the like), dimethyl ether, diethyl ether, tetrahydrofuran, cyclopentyl methyl ether, dimethoxyethane, and 1,4-dioxane.

Examples of amide compound solvents include N,N-dimethylformamide, N-methyl-2-pyrrolidone, N-ethyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropionamide, and hexamethylphosphoric triamide.

Examples of ketone compound solvents include acetone, methyl ethyl ketone, methyl isobutyl ketone, diethyl ketone, dipropyl ketone, diisopropyl ketone, diisobutyl ketone, and cyclohexanone.

Examples of aromatic compound solvents include benzene, toluene, xylene, chlorobenzene, and dichlorobenzene.

Examples of aliphatic compound solvents include hexane, heptane, octane, decane, and dodecane.

Examples of ester compound solvents include ethyl acetate, propyl acetate, butyl acetate, ethyl butyrate, butyl butyrate, butyl valerate, γ-butyrolactone, heptane, and the like.

Examples of carbonate compound solvents include ethylene carbonate, dimethyl carbonate, diethyl carbonate, ethyl methyl carbonate, propylene carbonate, and the like.

Examples of nitrile compound solvents include acetonitrile, propionitrile, butyronitrile, isobutyronitrile, and benzonitrile.

In the present invention, among these, the ether compound solvents, the ketone compound solvents, the aromatic compound solvents, the aliphatic compound solvents, and the ester compound solvents are preferably used, and the aromatic compound solvents and the aliphatic compound solvents are more preferably used. The boiling point of the dispersion medium at normal pressure (one atmosphere) is preferably 50° C. or higher and more preferably 80° C. or higher. The upper limit is preferably 250° C. or lower and more preferably 220° C. or lower. The dispersion media may be used singly or two or more dispersion media may be used in combination.

In the present invention, the amount of the dispersion medium in the solid electrolyte composition can be set to an arbitrary amount in consideration of the viscosity and the drying load of the solid electrolyte composition. Generally, the amount in the solid electrolyte composition is preferably 20 to 99% by mass.

(Positive Electrode Active Material)

To the solid electrolyte composition of the present invention, a positive electrode active material may be added. The solid electrolyte composition containing the positive electrode active material can be used as a composition for positive electrode materials. As the positive electrode active material, transition metal oxides are preferably used, and, among these, the positive electrode active material preferably has transition metals M^{a} (one or more elements selected from Co, Ni, Fe, Mn, Cu, and V). In addition, mixing elements M^{b} (metal elements belonging to Group I (Ia) of the periodic table other than lithium, elements belonging to Group II (IIa), Al, Ga, In, Ge, Sn, Pb, Sb, Bi, Si, P, B, and the like) may be mixed into the positive electrode active material.

Examples of the transition metal oxides include specific transition metal oxides including transition metal oxides represented by any one of Formulae (MA) to (MC) below and additionally include V₂O₅, MnO₂, and the like. As the positive electrode active material, a particulate positive electrode active material may be used.

Specifically, transition metal oxides capable of reversibly intercalating and deintercalating lithium ions can be used, and the specific transition metal oxides described above are preferably used.

Preferred examples of the transition metal oxides include oxides including the transition metal element M^{a} and the like. At this time, the mixing elements M^{b} (preferably Al) may be mixed into the positive electrode active material. The amount mixed is preferably 0 to 30 mol % with respect to the amount of the transition metal. Transition metal oxides synthesized by mixing Li and the transition metal so that the molar ratio of Li/M^{a} reaches 0.3 to 2.2 are more preferred.

[Transition Metal Oxide Represented by Formula (MA) (Bedded Salt-Type Structure)]

As lithium-containing transition metal oxides, among them, transition metal oxides represented by formula below are preferred.

LiₐM¹O_{b} Formula (MA)

In Formula (MA), M¹ is the same as M^{a}, and a preferred range thereof is also identical, a represents 0 to 1.2 (preferably 0.2 to 1.2) and is preferably 0.6 to 1.1. b represents 1 to 3 and is preferably 2. A part of M¹ may be substituted with the mixing element M^{b}.

The transition metal oxides represented by Formula (MA) typically have a bedded salt-type structure.

The transition metal oxides represented by Formula (MA) are more preferably transition metal oxides represented by individual formulae described below.

Li_{g}CoOₖ Formula (MA-1)

Li_{g}NiOₖ Formula (MA-2)

Li_{g}MnOₖ Formula (MA-3)

Li_{g}CoⱼNi₁₋ⱼOₖ Formula (MA-4)

Li_{g}NiⱼMn₁₋ⱼOₖ Formula (MA-5)

Li_{g}CoⱼNiᵢAl₁₋ⱼ₋ᵢOₖ Formula (MA-6)

Li_{g}CoⱼNiᵢMn₁₋ⱼ₋ᵢOₖ Formula (MA-7)

Here, g is the same as a and a preferred range thereof is also identical. j represents 0.1 to 0.9. i represents 0 to 1. However, 1−j−i reaches 0 or more. k is the same as b, and a preferred range thereof is also identical.

Specific examples of these transition metal oxides include LiCoO₂ (lithium cobalt oxide [LCO]), LiNi₂O₂(lithium nickelate). LiNi_{0.85}Co_{0.01}Al_{0.05}O₂ (lithium nickel cobalt aluminum oxide [NCA]), LiNi_{0.33}Co_{0.33}Mn_{0.33}O₂ (lithium nickel manganese cobalt oxide [NMC]), and LiNi_{0.5}Mn_{0.5}O₂ (lithium manganese nickelate).

Although there is partial duplication in expression, preferred examples of the transition metal oxides represented by Formula (MA) include transition metal oxides represented by formulae below when expressed in a different manner.

(i) Li_{g}Ni_{xc}Mn_{yc}Co_{zc}O₂ (xc>0.2, yc>0.2, zc≧0, xc+yc+zc=1)

Typical transition metal oxides:

Li_{g}Ni_{1/3}Mn_{1/3}Co_{1/3}O₂

Li_{g}Ni_{1/3}Mn_{1/2}O₂

(ii) Li_{g}Ni_{xd}CO_{yd}Al_{zd}O₂ (xd>0.7, yd>0.1, 0.1>zd≧0.05, xd+yd+zd=1)

Typical transition metal oxides:

Li_{g}Ni_{0.8}Co_{0.15}Al_{0.05}O₂

[Transition Metal Oxide Represented by Formula (MB) (Spinel-Type Structure)]

As lithium-containing transition metal oxides, among them, transition metal oxides represented by Formula (MB) below are also preferred.

Li_{c}M²₂O_{d} Formula (MB)

In Formula (MB), M² is the same as Mⁿ, and a preferred range thereof is also identical. c represents 0 to 2 and is preferably 0.2 to 2 and more preferably 0.6 to 1.5. d represents 3 to 5 and is preferably 4.

The transition metal oxides represented by Formula (MB) are more preferably transition metal oxides represented by individual formulae described below.

LiₘMn₂Oₙ Formula (MB-1)

LiₘMnₚAl₂₋ₚOₙ Formula (MB-2)

LiₘMnₚNi₂₋ₚOₙ Formula (MB-3)

m is the same as c and a preferred range thereof is also identical. n is the same as d and a preferred range thereof is also identical. p represents 0 to 2.

Examples of these transition metal oxides include LiMn₂O₄, LiMn_{1.5}Ni_{0.5}O₄.

Preferred examples of the transition metal oxides represented by Formula (MB) further include transition metal oxides represented by individual formulae described below.

LiCoMnO₄ Formula (a)

Li₂FeMn₃O₈ Formula (b)

Li₂CuMn₃O₈ Formula (c)

Li₂CrMn₃O₈ Formula (d)

Li₂NiMn₃O₈ Formula (e)

From the viewpoint of a high capacity and a high output, among the above-described transition metal oxides, electrodes including Ni are still more preferred.

[Transition Metal Oxide Represented by Formula (MC)]

Lithium-containing transition metal oxides are preferably lithium-containing transition metal phosphorus oxides, and, among these, transition metal oxides represented by Formula (MC) below are also preferred.

LiₑM³(PO₄)_{f} Formula (MC)

In Formula (MC), e represents 0 to 2 (preferably 0.2 to 2) and is preferably 0.5 to 1.5. f represents 1 to 5 and is preferably 1 to 2.

M³ represents one or more elements selected from the group consisting of V, Ti, Cr, Mn, Fe, Co, Ni, and Cu. M³ may be substituted with not only the mixing element M^{b} but also other metal such as Ti, Cr, Zn, Zr, or Nb. Specific examples include olivine-type iron phosphate salts such as LiFePO₄ and Li₃Fe₂(PO₄)₃, iron pyrophosphates such as LiFeP₂O₇, cobalt phosphates such as LiCoPO₄, monoclinic nasicon-type vanadium phosphate salt such as Li₃V₂(PO₄)₃ (lithium vanadium phosphate).

Meanwhile, the a, c, g, m, and e values representing the composition of Li are values changing due to charging and discharging and are, typically, evaluated as values in a stable state when Li is contained. In Formulae (a) to (e), the composition of Li is expressed using specific values, but these values also change due to the operation of batteries.

The average particle diameter of the positive electrode active material being used in the all solid state secondary battery of the present invention is not particularly limited. Meanwhile, the average particle diameter is preferably 0.1 m to 50 μm. In order to provide a predetermined particle diameter to the positive electrode active material, an ordinary crusher or classifier may be used. Positive electrode active materials obtained using a firing method may be used after being washed with water, an acidic aqueous solution, an alkaline aqueous solution, or an organic solvent. The average particle diameter of the positive electrode active material particles is measured using the same method as the method for measuring the average particle diameter of inorganic solid electrolyte particles described in the section of examples described below.

The concentration of the positive electrode active material is not particularly limited. Meanwhile, the concentration in the solid electrolyte composition is preferably 20 to 90% by mass and more preferably 40 to 80% by mass with respect to 100% by mass of the solid component. Meanwhile, when a positive electrode layer includes another inorganic solid (for example, a solid electrolyte), the above-described concentration is interpreted to include the concentration of the inorganic solid.

(Negative Electrode Active Material)

To the solid electrolyte composition of the present invention, a negative electrode active material may be added. The solid electrolyte composition containing the negative electrode active material can be used as a composition for negative electrode materials. As the negative electrode active material, negative electrode active materials capable of reversibly intercalating and deintercalating lithium ions are preferred. These materials are not particularly limited, and examples thereof include carbonaceous materials, metal oxides such as tin oxide and silicon oxide, metal complex oxides, a lithium single body or lithium alloys such as lithium aluminum alloys, metals capable of forming alloys with lithium such as Sn and Si, and the like. These materials may be used singly or two or more materials may be jointly used in an arbitrary combination and fractions. Among these, carbonaceous materials or lithium complex oxides are preferably used in terms of safety. In addition, the metal complex oxides are preferably capable of absorbing and emitting lithium. The materials are not particularly limited, but preferably contain at least one atom selected from titanium or lithium as a constituent component from the viewpoint of high-current density charging and discharging characteristics.

The carbonaceous materials being used as the negative electrode active material are materials substantially made of carbon. Examples thereof include petroleum pitch, natural graphite, artificial graphite such as highly oriented pyrolytic graphite, and carbonaceous material obtained by firing a variety of synthetic resins such as PAN-based resins or furfuryl alcohol resins. Furthermore, examples thereof also include a variety of carbon fibers such as PAN-based carbon fibers, cellulose-based carbon fibers, pitch-based carbon fibers, vapor-grown carbon fibers, dehydrated PVA-based carbon fibers, lignin carbon fibers, glassy carbon fibers, and active carbon fibers, mesophase microspheres, graphite whisker, flat graphite, and the like.

These carbonaceous materials can also be classified into non-graphitizable carbon materials and graphite-based carbon materials depending on the degree of graphitization. In addition, the carbonaceous materials preferably have the surface separation, the density, and the sizes of crystallites described in JP1987-22066A (JP-S62-22066A), JP1990-6856A (JP-H02-6856A), and JP1991-45473A (JP-H03-45473A). The carbonaceous materials do not need to be a sole material, and it is also possible to use the mixtures of a natural graphite and a synthetic graphite described in JP1993-90844A (JP-H05-90844A), the graphite having a coated layer described in JP1994-4516A (JP-H06-4516A), and the like.

The metal oxides and the metal complex oxides being applied as the negative electrode active material are particularly preferably amorphous oxides, and furthermore, chalcogenides which are reaction products between a metal element and an element belonging to Group XVI of the periodic table are also preferably used. The amorphous oxides mentioned herein refer to oxides having a broad scattering band having a peak of a 20 value in a range of 20° to 40° in an X-ray diffraction method in which CuKα rays are used and may have crystalline diffraction lines. The highest intensity in the crystalline diffraction line appearing at the 20 value of 40° or more and 70° or less is preferably 100 times or less and more preferably five times or less of the diffraction line intensity at the peak of the broad scattering line appearing at the 20 value of 20° or more and 400 or less and still more preferably does not have any crystalline diffraction lines.

In a compound group consisting of the amorphous oxides and the chalcogenides, amorphous oxides of semimetal elements and chalcogenides are more preferred, and elements belonging to Groups XIII (IIIB) to XV (VB) of the periodic table, oxides made of one element or a combination of two or more elements of Al, Ga, Si, Sn, Ge, Pb, Sb, and Bi, and chalcogenides are still more preferred. Specific examples of preferred amorphous oxides and chalcogenides include Ga₂O₃, SiO, GeO, SnO, SnO₂, PbO, PbO₂, Pb₂O₃, Pb₂O₄, Pb₃O₄, Sb₂O₃, Sb₂O₄, Sb₂O₅, Bi₂O₃, Bi₂O₄, SnSiO₃, GeS, SnS, SnS₂, PbS, PbS₂, Sb₂S₃, Sb₂S₅, SnSiS₃, and the like. In addition, these amorphous oxides may be complex oxides with lithium oxide, for example, Li₂SnO₂.

The average particle diameter of the negative electrode active material is preferably 0.1 μm to 60 μm. In order to provide a predetermined particle diameter, a well-known crusher or classifier is used. For example, a mortar, a ball mill, a sand mill, an oscillatory ball mill, a satellite ball mill, a planetary ball mill, a swirling airflow-type jet mill, a sieve, or the like is preferably used. During crushing, it is also possible to carry out wet-type crushing in which water or an organic solvent such as methanol is made to coexist as necessary. In order to provide a desired particle diameter, classification is preferably carried out. The classification method is not particularly limited, and it is possible to use a sieve, a wind powder classifier, or the like depending on the necessity. Both of dry-type classification and wet-type classification can be carried out. The average particle diameter of the negative electrode active material particles is measured using the same method as the method for measuring the average particle diameter of the inorganic solid electrolyte particles described in the section of examples described below.

The compositional formula of the compound obtained using the firing method can be computed using inductively coupled plasma (ICP) emission spectrometry as the measurement method or from the mass difference of powder before and after firing as a convenient method.

Preferred examples of negative electrode active materials that can be jointly used in the amorphous oxide negative electrode active material mainly containing Sn, Si, or Ge include carbon materials capable of absorbing and emitting lithium ions or lithium metals, lithium, lithium alloys, and metals capable of forming alloys with lithium.

The negative electrode active material preferably contains titanium atoms. More specifically, Li₄TiO₁₂ is preferred since the volume fluctuation during the absorption and emission of lithium ions is small and thus the high-speed charging and discharging characteristics are excellent and the deterioration of electrodes is suppressed, whereby it becomes possible to improve the service lives of lithium ion secondary batteries. When a specific negative electrode and, furthermore, a specific electrolytic solution are combined together, the stability of secondary batteries improves under a variety of operation conditions.

In the present invention, it is also preferable to apply negative electrode active materials containing Si elements. Generally, Si negative electrodes are capable of absorbing a larger number of Li ions than current carbon negative electrodes (graphite, acetylene black, and the like). That is, since the amount of Li ions absorbed per mass increases, it is possible to increase battery capacities. As a result, there is an advantage of being capable of elongating the battery-operating time, and the use in vehicle batteries and the like is expected in the future. On the other hand, it is known that the volume significantly changes due to the absorption and emission of Li ions, and there is also an example in which the volume expands approximately 1.2 to 1.5 times in carbon negative electrodes, but expands approximately three times in Si negative electrodes. Repetition of this expansion and contraction (repetition of charging and discharging) leads to insufficient durability of electrode layers, and examples thereof include a likelihood of the occurrence of insufficient contact and the shortening of the cycle service lives (battery service lives).

According to the solid electrolyte composition of the present invention, favorable durability (strength) is exhibited even in electrode layers which significantly expand and contract, and it is possible to more effectively exhibit the excellent advantages.

The concentration of the negative electrode active material is not particularly limited, but is preferably 10 to 80% by mass and more preferably 20 to 70% by mass with respect to 100% by mass of the solid component in the solid electrolyte composition. Meanwhile, when a negative electrode layer includes another inorganic solid (for example, a solid electrolyte), the above-described concentration is interpreted to include the concentration of the inorganic solid.

Meanwhile, in the above-described embodiment, an example in which the positive electrode active material or the negative electrode active material is added to the solid electrolyte composition according to the present invention has been described, but the present invention is not interpreted to be limited thereto.

For example, paste including a positive electrode active material or a negative electrode active material may be prepared using an ordinary polymer instead of the specific electrolytic crosslinking polymer described above. However, in the present invention, it is preferable to combine the specific electrolytic crosslinking polymer described above with the positive electrode active material or the negative electrode active material and use the combination as described above.

In addition, to the active material layers in the positive electrode and the negative electrode, a conduction aid may be appropriately added as necessary. As an ordinary conduction aid, it is possible to add graphite, carbon black, acetylene black. Ketjenblack, a carbon fiber, metal powder, a metal fiber, a polyphenylene derivative, or the like as an electron-conducting material.

<Collector (Metal Foil)>

The collector of the positive or negative electrode is preferably an electron conductor that does not chemically change. The collector of the positive electrode is preferably a collector obtained by treating the surface of aluminum or stainless steel in addition to aluminum, stainless steel, nickel, titanium, or the like with carbon, nickel, titanium, or silver, and, among these, aluminum and aluminum alloys are more preferred. The collector of the negative electrode is preferably aluminum, copper, stainless steel, nickel, or titanium and more preferably aluminum, copper, or a copper alloy.

Regarding the shape of the collector, generally, collectors having a film sheet-like shape are used, but it is also possible to use nets, punched collectors, lath bodies, porous bodies, foams, compacts of fiber groups, and the like.

The thickness of the collector is not particularly limited, but is preferably 1 μm to 500 μm. In addition, the surface of the collector is preferably provided with protrusions and recesses by means of a surface treatment.

<Production of all Solid State Secondary Battery>

The all solid state secondary battery may be produced using an ordinary method. Specific examples thereof include a method in which the solid electrolyte composition of the present invention is applied onto a metal foil that serves as the collector and an electrode sheet for a battery on which a coated film is formed is produced.

For example, a composition serving as a positive electrode material is applied onto a metal foil which is the positive electrode active material layer and then dried, thereby forming a positive electrode active material layer. Next, the solid electrolyte composition is applied onto a positive electrode sheet for a battery and then dried, thereby forming a solid electrolyte layer. Furthermore, a composition serving as a negative electrode material is applied and dried thereon, thereby forming a negative electrode active material layer. A collector (metal foil) for the negative electrode is overlaid thereon, whereby it is possible to obtain a structure of the all solid state secondary battery in which the solid electrolyte layer is sandwiched between the positive electrode layer and the negative electrode layer. Meanwhile, the respective compositions described above may be applied using an ordinary method. At this time, after the application of each of the composition forming the positive electrode active material layer, the composition forming the inorganic solid electrolyte layer (the solid electrolyte composition), and the composition forming the negative electrode active material layer, a drying treatment may be carried out or a drying treatment may be carried out after the application of multiple layers. The drying temperature is not particularly limited, but is preferably 30° C. or higher and more preferably 60° C. or higher. The upper limit is preferably 300° C. or lower and more preferably 250° C. or lower. When the compositions are heated in the above-described temperature range, it is possible to remove the dispersion medium and cause the compositions to fall into a solid state. Therefore, in the all solid state secondary battery, it is possible to obtain favorable bonding properties and favorable ion conductivity in the absence of pressure.

<Production of all Solid State Secondary Battery Formed by Crosslinking Electrolytic Crosslinking Polymer by Means of Charging and Discharging>

The all solid state secondary battery of the present invention contains the electrolytic crosslinking polymer that forms a crosslinking structure by means of electrolytic oxidation polymerization or electrolytic reduction polymerization. Therefore, when the all solid state secondary battery manufactured using the above-described method is charged or discharged at least once, it is possible to obtain all solid state secondary batteries formed by crosslinking the electrolytic crosslinking polymer.

Specifically, the electrolytic crosslinked body is formed by means of the electrolytic polymerization of the electrolytic crosslinking polymer being contained in the positive electrode active material layer or the negative electrode active material layer together with the inorganic solid electrolyte on the electrode surface after the assembly of batteries. In addition, the electrolytic crosslinking polymer may be crosslinked intentionally by applying voltage before the first charging and discharging of batteries or may be crosslinked in the charging and discharging process of batteries.

When the electrolytic crosslinking polymer is crosslinked, a crosslinking structure is formed between the polymers, an oxidized film or reduced film is formed between the inorganic solid electrolyte and the active material, and side reactions or decomposition between the active material and the inorganic solid electrolyte is suppressed. In addition, this oxidized film or reduced film also improves bonding properties. As a result, it is possible to provide all solid state secondary batteries having excellent cycle characteristics.

In addition, compared with all solid state secondary batteries produced using a crosslinked high-molecular-weight polymer as a binder, all solid state secondary batteries which are produced using the solid electrolyte composition containing the electrolytic crosslinking polymer, are electrolytic-polymerized by means of charging and discharging, and are crosslinked have superior cycle characteristics.

The latter all solid state secondary batteries are assumed to have excellent bonding properties since the all solid state secondary batteries are crosslinked in a state in which the electrolytic crosslinking polymer is sufficiently infiltrated between the inorganic solid electrolyte and the active material, and thus the electrolytic crosslinked body which is a binder is strongly bonded to the inorganic solid electrolyte and the active materials.

Furthermore, in a case in which the sulfide-based inorganic solid electrolyte is used, particularly, it is possible to effectively suppress the decomposition of the inorganic solid electrolyte by water.

Here, the electrolytic crosslinking polymer being used in the present invention is crosslinked by means of electrolytic polymerization and forms the electrolytic crosslinked body in a state of being dispersed in the composition together with the active materials and the inorganic solid electrolyte. Therefore, the electrolytic crosslinked body formed in a net shape between the active material and the inorganic solid electrolyte is assumed to be strongly bonded to the active material, and it is possible to confirm the electrolytic crosslinked body from the all solid state secondary battery after the formation using the following method.

That is, the all solid state secondary battery formed by crosslinking the electrolytic crosslinking polymer by means of charging and discharging is disassembled, only the active materials are removed, and the all solid state secondary battery is washed with an organic solvent. Organic substances being attached to the surfaces of the active materials after the washing can be confirmed through a surface element analysis or detection by means of a thermogravimetric/differential thermal analysis (TG-DTA).

In the electrolytic crosslinking polymer being used in the present invention, electrolytic oxidation polymerization or electrolytic reduction polymerization is induced by an electrolytic reaction, and a crosslinking structure is formed.

Specifically, electrolytic crosslinking polymers in which reduction polymerization is initiated from a charging and discharging potential (Li/Li⁺-based) of 1.5 V or more and a crosslinking structure is formed in the negative electrode active material layer or electrolytic crosslinking polymers in which oxidation polymerization is initiated from a charging and discharging potential (Li/Li⁺-based) of less than 4.5 V and a crosslinking structure is formed in the positive electrode active material layer are preferred.

The charging and discharging potential at which reduction polymerization is initiated is preferably 2 V or more and more preferably 2.5 V or more. The charging and discharging potential at which oxidation polymerization is initiated is preferably less than 4.3 V and more preferably less than 4 V.

The charging and discharging potential may be specified from the peak. The peak of the potential can be specified by producing a three-pole cell made up of an operation electrode, a reference electrode, and a counter electrode and carrying out an electrochemical measurement (cyclic voltammetry). The constitution of the three-pole cell and the measurement conditions of the electrochemical measurement are as described below.

<Constitution of Three-Pole Cell>
Operation electrode: An active material electrode produced on a platinum electrode using a sol-gel method or a sputtering method
Reference electrode: Lithium
Counter electrode: Lithium
Dilution medium: EC/EMC=½ LiPF₆ 1 M, manufactured by Kishida Chemical Co., Ltd.

Here, EC represents ethylene carbonate, and EMC represents ethyl methyl carbonate.

<Measurement Conditions>
Scanning rate: 1 mV/s
Measurement temperature: 25° C.

The positive electrode potential (Li/Li⁺-based) during charging and discharging is

(Positive electrode potential)=(negative electrode potential)+(battery voltage).

In a case in which lithium titanate is used as the negative electrode, the negative electrode potential is set to 1.55 V. In a case in which graphite is used as the negative electrode, the negative electrode potential is set to 0.1 V. The battery voltage is observed during charging, and the positive electrode potential is computed.

Here, in order to obtain the crosslinked electrolytic crosslinking polymer having effect of protecting favorable inorganic solid electrolytes and improving bonding properties and electron conductivity, the satisfaction of the following conditions is also preferably applied.

That is, the amount of the electrolytic crosslinking polymer added is preferably small since the film thickness decreases, and the area of the crosslinked electrolytic crosslinking polymer in contact with the active materials is preferably large. In addition, the ball mill mixing time of the positive electrode or negative electrode composition is preferably longer since the interaction between the electrolytic crosslinking polymer and the active materials improves. Furthermore, the electrolytic crosslinking polymer being used in the present invention preferably has electron-donating groups (alkyl groups and the like) in the vicinity of the carbon-carbon unsaturated bonds not contributing to aromaticity being contained in the main chain since the electrolytic crosslinking polymer is easily oxidation-polymerized and, conversely, preferably has electron-withdrawing groups since the electrolytic crosslinking polymer is easily reduction-polymerized.

<Applications of all Solid State Secondary Battery>

The all solid state secondary battery of the present invention can be applied to a variety of applications. Application aspects are not particularly limited, and, in the case of being mounted in electronic devices, examples thereof include notebook computers, pen-input personal computers, mobile personal computers, e-book players, mobile phones, cordless phone handsets, pagers, handy terminals, portable faxes, mobile copiers, portable printers, headphone stereos, video movies, liquid crystal televisions, handy cleaners, portable CDs, mini discs, electric shavers, transceivers, electronic notebooks, calculators, memory cards, portable tape recorders, radios, backup power supplies, memory cards, and the like. Additionally, examples of consumer applications include automobiles, electric vehicles, motors, lighting equipment, toys, game devices, road conditioners, watches, strobes, cameras, medical devices (pacemakers, hearing aids, shoulder massage devices, and the like), and the like. Furthermore, the all solid state secondary battery can be used for a variety of military applications and universe applications. In addition, the all solid state secondary battery can also be combined with solar batteries.

Among these, the all solid state secondary battery is preferably applied to applications for which a high capacity and high rate discharging characteristics are required. For example, in electricity storage facilities expected to have a high capacity in the future, high reliability becomes essential, and furthermore, the satisfaction of battery performance is required. In addition, high-capacity secondary batteries are mounted in electric vehicles and the like and are assumed to be used in domestic applications in which charging is carried out every day, and thus better reliability for overcharging is required. According to the present invention, it is possible to preferably cope with the above-described application aspects and exhibit excellent effects.

According to the preferred embodiment of the present invention, individual application aspects as described below are derived.

(1) Solid electrolyte compositions including active materials capable of intercalating and deintercalating ions of metals belonging to Group I or II of the periodic table (electrode compositions for positive electrodes and negative electrodes)

(2) Electrode sheets for a battery in which a film of the solid electrolyte composition is formed on a metal foil

(3) All solid state secondary batteries equipped with a positive electrode active material layer, a negative electrode active material layer, and a solid electrolyte layer in which at least any of the positive electrode active material layer, the negative electrode active material layer, or the solid electrolyte layer are layers constituted of the solid electrolyte composition

(4) Methods for manufacturing electrode sheets for a battery in which the solid electrolyte composition is disposed on a metal foil, and a film thereof is formed

(5) Methods for manufacturing an all solid state secondary battery in which all solid state secondary batteries are manufactured through the method for manufacturing an electrode sheet for a battery

(6) All solid state secondary batteries formed by electrolytic oxidation-polymerizing or electrolytic reduction-polymerizing the electrolytic crosslinking polymer by charging or discharging the all solid state secondary battery at least once

In addition, in the preferred embodiment of the present invention, the electrolytic crosslinked body is formed by means of charging and discharging after the manufacturing of the all solid state secondary battery, and thus it is possible to easily manufacture all solid state secondary batteries exhibiting an effect of improving cycle characteristics by suppressing side reactions or decomposition between the inorganic solid electrolyte and the active material and improving bonding properties.

All solid state secondary batteries refer to secondary batteries in which the positive electrode, the negative electrode, and the electrolyte are all constituted of solid. In other words, all solid state secondary batteries are differentiated from electrolytic solution-type secondary batteries in which a carbonate-based solvent is used as the electrolyte. Among these, the present invention is assumed to be an inorganic all solid state secondary battery. All solid state secondary batteries are classified into organic (high-molecular-weight) all solid state secondary batteries in which a high-molecular-weight compound such as polyethylene oxide is used as the electrolyte and inorganic all solid state secondary batteries in which Li—P—S, LLT, LLZ, or the like is used. Meanwhile, the application of high-molecular-weight compounds to inorganic all solid state secondary batteries is not inhibited, and high-molecular-weight compounds can be applied as the positive electrode active material, the negative electrode active material, and the binder of the inorganic solid electrolyte particles.

Inorganic solid electrolytes are differentiated from electrolytes in which the above-described high-molecular-weight compound is used as an ion conductive medium (high-molecular-weight electrolyte), and inorganic compounds serve as ion conductive media. Specific examples thereof include Li—P—S, LLT, and LLZ. Inorganic solid electrolytes do not emit positive ions (Li ions) and exhibit an ion transportation function. In contrast, there are cases in which materials serving as an ion supply source which is added to electrolytic solutions or solid electrolyte layers and emits positive ions (Li ions) are referred to as electrolytes; however, when differentiated from electrolytes as the ion transportation materials, the materials are referred to as “electrolyte salts” or “supporting electrolytes”. Examples of the electrolyte salts include lithium bistrifluoromethanesulfonylimide (LiTFSI).

In the present invention, “compositions” refer to mixtures obtained by uniformly mixing two or more components. However, compositions may partially include agglomeration or uneven distribution as long as the compositions substantially maintain uniformity and exhibit desired effects.

### EXAMPLES

Hereinafter, the present invention will be described in more detail on the basis of examples. Meanwhile, the present invention is not interpreted to be limited thereto. In the following examples, “parts” and “%” are mass-based unless particularly otherwise described.

Synthesis of Polymer in the Present Invention

Synthesis of Exemplary Compound (A-1)

Trans-2-butenediol (manufactured by Tokyo Chemical Industry Co., Ltd.) (8.8 g) and triethylamine (5.0 g) were added to a 300 mL three-neck flask and were diluted with THF (100 mL). While this solution was heated and stirred at 50° C., terephthalate chloride (20.3 g) was added thereto, and furthermore, the components were continuously stirred at 50° C. for three hours. The reaction solution was added to a solvent mixture (distilled water/methanol=80/20) (500 mL), and re-precipitation of the polymer was carried out. The obtained powder was filtered and dried in a vacuum at 80° C., thereby obtaining a polymer illustrated as Exemplary Compound (A-1). The mass average molecular weight was measured by means of GPC to be 76,300. In addition, the glass transition temperature was 58° C.

Synthesis of Exemplary Compound (A-26)

Trans-2-butenediol (manufactured by Tokyo Chemical Industry Co., Ltd.) (3.6 g), Polybd (registered trademark) R-45H′ (trade name, manufactured by Idemitsu Kosan Co., Ltd.) (20.5 g), and isophorone diisocyanate (8.5 g) (manufactured by Wako Pure Chemical Industries, Ltd.) were added to a 300 mL three-neck flask and were diluted with DMF (100 mL). NEOSTAN (registered trademark) U-600 (trade name, bismuth-based catalyst, manufactured by Nittoh Chemical Co., Ltd.) (0.12 g) was added to this solution, and the mixture was heated to 80° C. and was continuously stirred at 80° C. for six hours. The reaction solution was added to methanol (500 mL), and re-precipitation of the polymer was carried out. The supernatant solution was decanted, the obtained rubber-form solid was filtered and dried in a vacuum at 80° C., thereby obtaining a polymer illustrated as Exemplary Compound (A-26). The mass average molecular weight was measured by means of GPC to be 54,900. In addition, the glass transition temperature was 10° C.

Syntheses of Exemplary Compounds (A-3), (A-12), (A-13), (A-19), (A-21) and (A-27) to (A-32)

Polymers illustrated as Exemplary Compounds (A-3), (A-12), (A-13), (A-19), (A-21) and (A-27) to (A-32) were obtained using the same method as in the syntheses of Exemplary Compounds (A-1) and (A-26) or an ordinary method.

Meanwhile, the mass average molecular weights and the glass transition temperatures are summarized in Tables 2 to 4.

Meanwhile, the water content of the synthesized polymer was computed by using a polymer which had been dried in a vacuum at 80° C. as a specimen, measuring the amount (g) of moisture in the specimen using a Karl Fischer liquid AQUAMICRON AX (trade name, manufactured by Mitsubishi Chemical Corp.) and the Karl Fischer method, and dividing the measured amount (g) of moisture by the mass (g) of the specimen.

The water contents of the polymers were all 100 ppm or less.

<Method for Measuring Glass Transition Temperature (Tg)>

For the obtained polymers, the glass transition temperatures (Tg) of the synthesized exemplary compounds were measured using a dried specimen and a differential scanning calorimeter “X-DSC7000” (trade name, SII•NanoTechnology Inc.) under the following conditions. The glass transition temperature of the same specimen was measured twice, and the measurement result of the second measurement was used.

Atmosphere of the measurement chamber: nitrogen (50 mL/min)

Temperature-increase rate: 5° C./min

Measurement-start temperature: −100° C.

Measurement-end temperature: 200° C.

Specimen plate: aluminum plate

Mass of the measurement specimen: 5 mg

Estimation of Tg: Tg is estimated by rounding off the middle temperature between the declination-start point and the declination-end point in the DSC chart to the integer.

Synthesis of Sulfide-Based Inorganic Solid Electrolyte (Li—P—S-Based Glass)

The sulfide solid electrolyte of the present invention was synthesized with reference to a non-patent document of T. Ohtomo, A. Hayashi, M. Tatsumisago, Y. Tsuchida, S. Hama, K. Kawamoto, Journal of Power Sources, 233, (2013), pp. 231 to 235 and A. Hayashi, S. Hama, H. Morimoto, M. Tatsumisago, T. Minami, Chem. Lett., (2001), pp. 872 and 873.

Specifically, in a globe box under an argon atmosphere (dew point: −70° C.), lithium sulfide (Li₂S, manufactured by Aldrich-Sigma, Co. LLC. Purity: >99.98%) (2.42 g) and diphosphorus pentasulfide (P₂Ss, manufactured by Aldrich-Sigma, Co. LLC. Purity: >99%) (3.90 g) were respectively weighed, injected into an agate mortar, and mixed using an agate muddler for five minutes. Meanwhile, the molar ratio between Li₂S and P₂S₅ was set to Li₂S:P₂S=75:25. The components were mixed together for five minutes on the agate mortar using an agate muddler.

66 zirconia beads having a diameter of 5 mm were injected into a 45 mL zirconia container (manufactured by Fritsch Japan Co., Ltd.), the all amount of the mixture of the lithium sulfide and the diphosphorus pentasulfide was injected thereinto, and the container was completely sealed in an argon atmosphere. The container was set in a planetary ball mill P-7 (trade name) manufactured by Fritsch Japan Co., Ltd., mechanical milling was carried out at a temperature of 25° C. and a rotation speed of 510 rpm for 20 hours, thereby obtaining yellow powder (6.20 g) of a sulfide solid electrolyte material (Li—P—S-based glass).

### Example 1

Manufacturing of Solid Electrolyte Composition

(1) Manufacturing of Solid Electrolyte Composition (K-1)

180 zirconia beads having a diameter of 5 mm were injected into a 45 mL zirconia container (manufactured by Fritsch Japan Co., Ltd.), and an inorganic solid electrolyte LLZ (Li₇La₃Zr₂O₁₂, lithium lanthanum zirconate, average particle diameter: 5.06 μm, manufactured by Toshima Manufacturing Co., Ltd.) (9.0 g), Exemplary Compound (A-1) of the polymer (0.3 g), and toluene (15.0 g) as a dispersion medium were injected thereinto. After that, the container was set in a planetary ball mill P-7 (trade name) manufactured by Fritsch Japan Co., Ltd., the components were continuously stirred at a temperature of 25° C. and a rotation speed of 300 rpm for two hours, thereby manufacturing a solid electrolyte composition (K-1).

(2) Manufacturing of Solid Electrolyte Composition (K-2)

180 zirconia beads having a diameter of 5 mm were injected into a 45 mL zirconia container (manufactured by Fritsch Japan Co., Ltd.), and the Li—P—S-based glass synthesized above (9.0 g), Exemplary Compound (A-1) of the polymer (0.3 g), and heptane (15.0 g) as a dispersion medium were injected thereinto. After that, the container was set in a planetary ball mill P-7 (trade name) manufactured by Fritsch Japan Co., Ltd., the components were continuously stirred at a temperature of 25° C. and a rotation speed of 300 rpm for two hours, thereby manufacturing a solid electrolyte composition (K-2).

(3) Manufacturing of Solid Electrolyte Compositions (K-3) to (K-10) and (HK-1) to (HK-3)

Solid electrolyte compositions (K-3) to (K-10) and (HK-1) to (HK-3) were manufactured using the same method as for the solid electrolyte compositions (K-1) and (K-2) except for the fact that the constitutions were changed as shown in Table 2 below.

Meanwhile, for the solid electrolyte composition (K-10), lithium bistrifluoromethanesulfonylimide (LiTFSI) was dispersed using a ball mill at the same time as the inorganic solid electrolyte or the polymer.

The constitutions of the solid electrolyte compositions are summarized in Table 2 below.

Here, the solid electrolyte compositions (K-1) to (K-10) are the solid electrolyte composition of the present invention, and the solid electrolyte compositions (HK-1) to (HK-3) are comparative solid electrolyte compositions.

Meanwhile, the unsaturated bond percentages (%) are shown after being rounded off to one decimal place.

In addition, “-” in the table indicates that the corresponding component was not used or, accordingly, the content of the component was 0 parts by mass, or the component is not applicable.

TABLE 2

| | Polymer | | | | | Solid | | Lithium | | Dispersion | |
|---|---|---|---|---|---|---|---|---|---|---|---|
| | | | | | Unsaturated | electrolyte | | salt | | medium | |
| Solid | | Parts | | | bond | | Parts | | Parts | | Parts |
| electrolyte | | by | | Tg | percentage | | by | | by | | by |
| composition | Type | mass | Mw | (° C.) | (%) | Type | mass | Type | mass | Type | mass |
| K-1 | A-1 | 0.3 | 76,300 | 58 | 9.1 | LLZ | 9.0 | — | — | Toluene | 15.0 |
| K-2 | A-1 | 0.3 | 76,300 | 58 | 9.1 | Li—P—S | 9.0 | — | — | Heptane | 15.0 |
| K-3 | A-26 | 0.3 | 54,900 | 10 | 19.5 | LLZ | 9.0 | — | — | Toluene | 15.0 |
| K-4 | A-26 | 0.3 | 54,900 | 10 | 19.5 | Li—P—S | 9.0 | — | — | Heptane | 15.0 |
| K-5 | A-12 | 0.3 | 37,800 | 43 | 12.5 | Li—P—S | 9.0 | — | — | Octane | 15.0 |
| K-6 | A-19 | 0.3 | 63,400 | 172 | 3.8 | Li—P—S | 9.0 | — | — | Octane | 15.0 |
| K-7 | A-28 | 0.3 | 42,100 | 49 | 27.6 | Li—P—S | 9.0 | — | — | Toluene | 15.0 |
| K-8 | A-29 | 0.3 | 37,600 | −3 | 17.8 | Li—P—S | 9.0 | — | — | Toluene | 15.0 |
| K-9 | A-32 | 0.3 | 41,700 | 5 | 16.5 | Li—P—S | 9.0 | — | — | Heptane | 15.0 |
| K-10 | A-32 | 0.3 | 41,700 | 5 | 16.5 | Li—P—S | 9.0 | LiTFSI | 0.1 | Heptane | 15.0 |
| HK-1 | — | — | — | — | — | Li—P—S | 9.0 | — | — | Heptane | 15.0 |
| HK-2 | SBR | 0.3 | 125,000 | −56 | 25.0 | Li—P—S | 9.0 | — | — | Heptane | 15.0 |
| HK-3 | HSBR | 0.3 | 178,900 | −62 | 0.0 | Li—P—S | 9.0 | — | — | Heptane | 15.0 |

<Note in Table 2>
LLZ: Li₇La₃Zr₂O₁₂ (lithium lanthanum zirconate, average particle diameter: 5.06 μm, manufactured by Toshima Manufacturing Co., Ltd.)
Li—P—S: Li—P—S-based glass synthesized above
SBR: Styrene butadiene rubber
HSBR: Hydrogenated styrene butadiene rubber
LiTFSI: Lithium bistrifluoromethanesulfonylimide

(Measurement of Average Particle Diameter of Inorganic Solid Electrolyte Particles)

The average particle diameter of the inorganic solid electrolyte particles was measured in the following order. Inorganic particles were dispersed using water (heptane in a case in which a substance that was unstable in water was dispersed), thereby preparing 1% by mass of a dispersion liquid. The volume-average particle diameter of the inorganic solid electrolyte particles was measured using this dispersion liquid specimen and a “laser diffraction/scattering-type particle size distribution measurement instrument LA-920” (trade name, manufactured by Horiba Ltd.).

Manufacturing of Composition for Secondary Battery Positive Electrode

(1) Manufacturing of Composition for Positive Electrode (U-1)

180 zirconia beads having a diameter of 5 mm were injected into a 45 mL zirconia container (manufactured by Fritsch Japan Co., Ltd.), and an inorganic solid electrolyte LLZ (Li₇La₃Zr₂O₁₂, lithium lanthanum zirconate, average particle diameter: 5.06 μm, manufactured by Toshima Manufacturing Co., Ltd.) (2.7 g), Exemplary Compound (A-1) of the polymer (0.3 g), and toluene (12.3 g) as a dispersion medium were injected thereinto. After that, the container was set in a planetary ball mill P-7 (trade name) manufactured by Fritsch Japan Co., Ltd., the components were continuously mechanically dispersed at a temperature of 25° C. and a rotation speed of 300 rpm for two hours, then, LCO (LiCoO₂, lithium cobalt oxide, manufactured by Nippon Chemical Industrial Co., Ltd.) (7.0 g) was injected into the container as an active material, similarly, the container was set in a planetary ball mill P-7 (trade name) manufactured by Fritsch Japan Co., Ltd., and the components were continuously mixed together at a temperature of 25° C. and a rotation speed of 100 rpm for 15 minutes, thereby manufacturing a composition for a positive electrode (U-1).

(2) Manufacturing of Composition for Positive Electrode (U-2)

180 zirconia beads having a diameter of 5 mm were injected into a 45 mL zirconia container (manufactured by Fritsch Japan Co., Ltd.), and the Li—P—S-based glass synthesized above (2.7 g), Exemplary Compound (A-1) of the polymer (0.3 g), and toluene (12.3 g) as a dispersion medium were injected thereinto. After that, the container was set in a planetary ball mill P-7 (trade name) manufactured by Fritsch Japan Co., Ltd., the components were continuously mixed at a temperature of 25° C. and a rotation speed of 300 rpm for two hours, then, NMC (Li(Ni_{1/3}Mn_{1/3}Co_{1/3})O₂ nickel, manganese, lithium cobalt oxide, manufactured by Nippon Chemical Industrial Co., Ltd.) (7.0 g) was injected into the container as an active material, similarly, the container was set in a planetary ball mill P-7 (trade name) manufactured by Fritsch Japan Co., Ltd., and the components were continuously mixed together at a temperature of 25° C. and a rotation speed of 200 rpm for 15 minutes, thereby manufacturing a composition for a positive electrode (U-2).

(3) Manufacturing of Compositions for Positive Electrode (U-3) to (U-10) and (HU-1) to (HU-3)

Compositions for the positive electrode (U-3) to (U-10) and (HU-1) to (HU-3) were manufactured using the same method as for the compositions for the positive electrode (U-1) and (U-2) except for the fact that the constitutions were changed as shown in Table 3 below.

Meanwhile, for the composition for the positive electrode (U-10), lithium bistrifluoromethanesulfonylimide (LiTFSI) was dispersed using a ball mill at the same time as the inorganic solid electrolyte or the polymer.

The constitutions of the compositions for the positive electrode are summarized in Table 3 below.

Here, the compositions for the positive electrode (U-1) to (U-10) are the composition for the positive electrode of the present invention, and the compositions for the positive electrode (HU-1) to (HU-3) are comparative compositions for the positive electrode.

TABLE 3

| | Polymer | | | | | Solid | | Positive electrode | | Lithium | | Dispersion | |
|---|---|---|---|---|---|---|---|---|---|---|---|---|---|
| | | | | | Unsaturated | electrolyte | | active material | | salt | | medium | |
| Composition | | Parts | | | bond | | Parts | | Parts | | Parts | | Parts |
| for positive | | by | | Tg | percentage | | by | | by | | by | | by |
| electrode | Type | mass | Mw | (° C.) | (%) | Type | mass | Type | mass | Type | mass | Type | mass |
| U-1 | A-1 | 0.3 | 76,300 | 58 | 9.1 | LLZ | 2.7 | LCO | 7.0 | — | — | Toluene | 12.3 |
| U-2 | A-1 | 0.3 | 76,300 | 58 | 9.1 | Li—P—S | 2.7 | NMC | 7.0 | — | — | Heptane | 12.3 |
| U-3 | A-26 | 0.3 | 54,900 | 10 | 19.5 | LLZ | 2.7 | LCO | 7.0 | — | — | Toluene | 12.3 |
| U-4 | A-26 | 0.3 | 54,900 | 10 | 19.5 | Li—P—S | 2.7 | NMC | 7.0 | — | — | Heptane | 12.3 |
| U-5 | A-13 | 0.3 | 54,500 | 32 | 20.0 | Li—P—S | 2.7 | LCO | 7.0 | — | — | Octane | 12.3 |
| U-6 | A-21 | 0.3 | 163,100 | 222 | 5.3 | Li—P—S | 2.7 | NMC | 7.0 | — | — | Octane | 12.3 |
| U-7 | A-27 | 0.3 | 44,700 | −10 | 21.2 | Li—P—S | 2.7 | NMC | 7.0 | — | — | Toluene | 12.3 |
| U-8 | A-29 | 0.3 | 37,600 | −3 | 17.8 | Li—P—S | 2.7 | NMC | 7.0 | — | — | Toluene | 12.3 |
| U-9 | A-31 | 0.3 | 31,900 | −33 | 20.9 | Li—P—S | 2.7 | NMC | 7.0 | — | — | Heptane | 12.3 |
| U-10 | A-32 | 0.3 | 41,700 | 5 | 16.5 | Li—P—S | 2.7 | NMC | 7.0 | LiTFSI | 0.1 | Heptane | 12.3 |
| HU-1 | — | — | — | — | — | Li—P—S | 2.7 | NMC | 7.0 | — | — | Heptane | 12.3 |
| HU-2 | SBR | 0.3 | 125,000 | −56 | 25.0 | Li—P—S | 2.7 | NMC | 7.0 | — | — | Heptane | 12.3 |
| HU-3 | HSBR | 0.3 | 178,900 | −62 | 0.0 | Li—P—S | 2.7 | NMC | 7.0 | — | — | Dioxane | 12.3 |

<Note in Table 3>
LLZ: Li₇La₃Zr₂O₁₂ (lithium lanthanum zirconate, average particle diameter: 5.06 μm, manufactured by Toshima Manufacturing Co., Ltd.)
Li—P—S: Li—P—S-based glass synthesized above
LCO: LiCoO₂ lithium cobaltoxide
NMC: Li(Ni_{1/3}Mn_{1/3}Co_{1/3})O₂ nickel, manganese, lithium cobalt oxide
SBR: Styrene butadiene rubber
HSBR: Hydrogenated styrene butadiene rubber
LiTFSI: Lithium bistrifluoromethanesulfonylimide

Manufacturing of Composition for Secondary Battery Negative Electrode

(1) Manufacturing of Composition for Negative Electrode (S-1)

180 zirconia beads having a diameter of 5 mm were injected into a 45 mL zirconia container (manufactured by Fritsch Japan Co., Ltd.), and an inorganic solid electrolyte LLZ (Li₇La₃Zr₂O₁₂, lithium lanthanum zirconate, average particle diameter: 5.06 μm, manufactured by Toshima Manufacturing Co., Ltd.) (5.0 g), Exemplary Compound (A-1) of the polymer (0.5 g), and toluene (12.3 g) as a dispersion medium were injected thereinto. The container was set in a planetary ball mill P-7 (trade name) manufactured by Fritsch Japan Co., Ltd., the components were continuously mechanically dispersed at a temperature of 25° C. and a rotation speed of 300 rpm for two hours, then, acetylene black (7.0 g) was injected into the container, similarly, the container was set in a planetary ball mill P-7 (trade name) manufactured by Fritsch Japan Co., Ltd., and the components were continuously mixed together at a temperature of 25° C. and a rotation speed of 100 rpm for 15 minutes, thereby manufacturing a composition for a negative electrode (S-1).

(2) Manufacturing of Composition for Negative Electrode (S-2)

180 zirconia beads having a diameter of 5 mm were injected into a 45 mL zirconia container (manufactured by Fritsch Japan Co., Ltd.), and the Li—P—S-based glass synthesized above (2.7 g), Exemplary Compound (A-1) of the polymer (0.5 g), and heptane (12.3 g) as a dispersion medium were injected thereinto. The container was set in a planetary ball mill P-7 (trade name) manufactured by Fritsch Japan Co., Ltd., the components were continuously mixed at a temperature of 25° C. and a rotation speed of 300 rpm for two hours, then, acetylene black (7.0 g) was injected into the container as an active material, similarly, the container was set in a planetary ball mill P-7 (trade name) manufactured by Fritsch Japan Co., Ltd., and the components were continuously mixed together at a temperature of 25° C. and a rotation speed of 200 rpm for 15 minutes, thereby manufacturing a composition for a negative electrode (S-2).

(3) Manufacturing of Compositions for Negative Electrode (S-3) to (S-10) and (HIS-1) to (HS-4)

Compositions for the negative electrode (S-3) to (S-10) and (HS-1) to (HS-4) were manufactured using the same method as for the compositions for the negative electrode (S-1) and (S-2) except for the fact that the constitutions were changed as shown in Table 4 below.

Meanwhile, for the composition for the negative electrode (S-10), lithium bistrifluoromethanesulfonylimide (LiTFSI) was dispersed using a ball mill at the same time as the inorganic solid electrolyte or the polymer.

The constitutions of the compositions for the negative electrode are summarized in Table 4 below.

Here, the compositions for the negative electrode (S-1) to (S-10) are the composition for the negative electrode of the present invention, and the compositions for the negative electrode (HS-1) to (HS-4) are comparative compositions for the negative electrode.

TABLE 4

| | Polymer | | | | | Solid | | Negative electrode | | Lithium | | Dispersion | |
|---|---|---|---|---|---|---|---|---|---|---|---|---|---|
| | | | | | Unsaturated | electrolyte | | active material | | salt | | medium | |
| Composition | | Parts | | | bond | | Parts | | Parts | | Parts | | Parts |
| for negative | | by | | Tg | percentage | | by | | by | | by | | by |
| electrode | Type | mass | Mw | (° C.) | (%) | Type | mass | Type | mass | Type | mass | Type | mass |
| S-1 | A-1 | 0.5 | 76,300 | 58 | 9.1 | LLZ | 5.0 | AB | 7.0 | — | — | Toluene | 12.3 |
| S-2 | A-1 | 0.5 | 76,300 | 58 | 9.1 | Li—P—S | 5.0 | AB | 7.0 | — | — | Heptane | 12.3 |
| S-3 | A-26 | 0.5 | 54,900 | 10 | 19.5 | LLZ | 5.0 | AB | 7.0 | — | — | Toluene | 12.3 |
| S-4 | A-26 | 0.5 | 54,900 | 10 | 19.5 | Li—P—S | 5.0 | AB | 7.0 | — | — | Heptane | 12.3 |
| S-5 | A-12 | 0.5 | 37,800 | 43 | 12.5 | Li—P—S | 5.0 | AB | 7.0 | — | — | Heptane | 12.3 |
| S-6 | A-19 | 0.5 | 63,400 | 172 | 3.8 | Li—P—S | 5.0 | AB | 7.0 | — | — | Heptane | 12.3 |
| S-7 | A-27 | 0.5 | 44,700 | −10 | 21.2 | Li—P—S | 5.0 | AB | 7.0 | — | — | Heptane | 12.3 |
| S-8 | A-30 | 0.5 | 56,100 | −6 | 16.9 | Li—P—S | 5.0 | AB | 7.0 | — | — | Heptane | 12.3 |
| S-9 | A-32 | 0.5 | 41,700 | 5 | 16.5 | Li—P—S | 5.0 | AB | 7.0 | — | — | Heptane | 12.3 |
| S-10 | A-32 | 0.5 | 41,700 | 5 | 16.5 | Li—P—S | 5.0 | AB | 7.0 | LiTFSI | 0.1 | Heptane | 12.3 |
| HS-1 | — | — | — | — | — | Li—P—S | 5.0 | AB | 7.0 | — | — | Heptane | 12.3 |
| HS-2 | PVdF | 0.5 | 150,000 | −50 | 0.0 | Li—P—S | 5.0 | AB | 7.0 | — | — | Dibutyl | 12.3 |
| | | | | | | | | | | | | ether | |
| HS-3 | SBR | 0.5 | 125,000 | −56 | 25.0 | Li—P—S | 5.0 | AB | 7.0 | — | — | Heptane | 12.3 |
| HS-4 | HSBR | 0.5 | 178,900 | −62 | 0.0 | Li—P—S | 5.0 | AB | 7.0 | — | — | Dioxane | 12.3 |

<Note in Table 4>
LLZ: Li₇La₃Zr₂O₁₂ (lithium lanthanum zirconate, average particle diameter: 5.06 μm, manufactured by Toshima Manufacturing Co., Ltd.)
Li—P—S: Li—P—S-based glass synthesized above
PVdF: Polyvinylene difluoride
SBR: Styrene butadiene rubber
HSBR; Hydrogenated styrene butadiene rubber
AB: Acetylene black
LiTFSI: Lithium bistrifluoromethanesulfonylimide

Manufacturing of Positive Electrode Sheet for Secondary Battery

The composition for a secondary battery positive electrode manufactured above was applied onto a 20 μm-thick aluminum foil using an applicator capable of adjusting the clearance, heated at 80° C. for one hour, then, furthermore, heated at 110° C. for one hour, and a coating solvent was dried. After that, the composition was heated and pressurized using a heat press machine so as to obtain an arbitrary density, thereby manufacturing a positive electrode sheet for a secondary battery.

Manufacturing of Electrode Sheet for Secondary Battery

The solid electrolyte composition manufactured above was applied onto the positive electrode sheet for a secondary battery manufactured above using an applicator capable of adjusting the clearance, heated at 80° C. for one hour, and then, furthermore, heated at 110° C. for one hour. After that, the composition for a secondary battery negative electrode manufactured above was further applied onto the dried solid electrolyte composition, heated at 80° C. for one hour, and then, furthermore, heated at 110° C. for one hour. A 20 μm-thick copper foil was placed on the negative electrode layer, heated and pressurized using a heat press machine so as to obtain an arbitrary density, thereby manufacturing Test Nos. 101 to 110 and c11 to c14 of the electrode sheets for a secondary battery shown in Table 5. These electrode sheets for a secondary battery have the constitution of FIG. 1. The positive electrode layer, the negative electrode layer, and the solid electrolyte layer respectively have film thicknesses shown in Table 5 below.

Manufacturing of all Solid State Secondary Battery

A disc-shaped piece having a diameter of 14.5 mm was cut out from the electrode sheet for a secondary battery 15 manufactured above, put into a 2032-type stainless steel coin case 14 into which a spacer and a washer were combined under a humidity condition of a dew point of −60° C., and a confining pressure (a screw-fastening pressure: 8 N) was applied from the outside of the coin case 14 using a testing body illustrated in FIG. 2, thereby manufacturing all solid state secondary batteries 13 of Test Nos. 101 to 110 and c11 to c14 shown in Table 5 below. Meanwhile, in FIG. 2, reference sign 11 indicates an upper portion-supporting plate, reference sign 12 indicates a lower portion-supporting plate, and reference sign S indicates a spring.

On the all solid state secondary batteries of Test Nos. 101 to 110 and c11 to c14 manufactured above, the following evaluations were carried out.

<Evaluation of Battery Voltage>

The battery voltage of the all solid state secondary battery manufactured above was measured using a charging and discharging evaluation device “TOSCAT-3000” (trade name: manufactured by Toyo System Co., Ltd.).

Charging was carried out at a current density of 2 A/m² until the battery voltage reached 4.2 V, and, after the battery voltage reached 4.2 V, constant-voltage charging was carried out until the current density reached less than 0.2 A/m². Discharging was carried out at a current density of 2 A/m² until the battery voltage reached 3.0 V. This charging and discharging was repeated, the battery voltage after 5 mAh/g discharging in the third cycle was read and was evaluated using the following references. Meanwhile, the evaluation ranking of “C” or higher are the pass levels of the present testing.

(Evaluation References)

A: 4.0 V or more

B: 3.9 V or more and less than 4.0 V

C: 3.8 V or more and less than 3.9 V

D: Less than 3.8 V

<Evaluation of Cycle Characteristics>

The cycle characteristics of the all solid state secondary battery manufactured above were measured using a charging and discharging evaluation device “TOSCAT-3000” (trade name: manufactured by Toyo System Co., Ltd.).

Charging and discharging was carried out under the same conditions as those in the battery voltage evaluation. The discharge capacity in the third cycle was considered as 100, and the cycle characteristics were evaluated using the following references from the number of times of the cycle when the discharging capacity reached less than 80. Meanwhile, the evaluation ranking of “B” or higher are the pass levels of the present testing.

(Evaluation References)

A: 50 times or more

B: 40 times or more and less than 50 times

C: 30 times or more and less than 40 times

D: Less than 30 times

The constitutions and the evaluation results of the electrode sheets for a secondary battery and the all solid state secondary batteries are summarized in Table 5 below.

Here, Test Nos. 101 to 110 are electrode sheets for a secondary battery and all solid state secondary batteries in which the polymer being used in the present invention was used, and Test Nos. c11 to c14 are electrode sheets for a secondary battery and all solid state secondary batteries in which the comparative polymer was used.

Meanwhile, in Table 5 below, the battery voltage is abbreviated as the voltage.

TABLE 5

| | Positive | | Solid | | Negative | | | |
|---|---|---|---|---|---|---|---|---|
| | electrode | | electrolyte | | electrode | | | |
| | layer | | layer | | layer | | Battery | |
| | | Film | | Film | | Film | evaluation | |
| | | thick- | | thick- | | thick- | | Cycle |
| Test | Compo- | ness | Compo- | ness | Compo- | ness | Volt- | charac- |
| No. | sition | (μm) | sition | (μm) | sition | (μm) | age | teristics |
| 101 | U-2 | 80 | K-2 | 30 | S-2 | 80 | C | B |
| 102 | U-4 | 79 | K-4 | 34 | S-4 | 82 | C | B |
| 103 | U-5 | 87 | K-5 | 32 | S-5 | 83 | B | B |
| 104 | U-6 | 86 | K-6 | 33 | S-6 | 85 | B | B |
| 105 | U-7 | 75 | K-7 | 34 | S-7 | 72 | A | B |
| 106 | U-8 | 88 | K-8 | 33 | S-8 | 81 | B | A |
| 107 | U-9 | 83 | K-9 | 32 | S-9 | 86 | A | A |
| 108 | U-10 | 75 | K-10 | 33 | S-10 | 87 | A | A |
| 109 | U-9 | 86 | K-5 | 32 | S-4 | 78 | A | A |
| 110 | U-9 | 75 | K-5 | 31 | S-5 | 79 | A | A |
| c11 | HU-1 | 82 | HK-1 | 30 | HS-1 | 80 | C | D |
| c12 | HU-2 | 83 | HK-2 | 31 | HS-2 | 81 | D | A |
| c13 | HU-3 | 84 | HK-3 | 32 | HS-3 | 82 | D | B |
| c14 | HU-2 | 85 | HK-2 | 33 | HS-4 | 83 | D | C |

As is clear from the results shown in Table 5, the all solid state secondary battery of the present invention in which the polymer having hetero atoms and carbon-carbon unsaturated bonds not contributing to aromaticity in the main chain (the all solid state secondary batteries of Test Nos. 101 to 110) has a high battery voltage and high cycle characteristics.

On the other hand, the all solid state secondary battery of Test No. c11 of the comparative example in which any layers did not have the polymer had an insufficient battery voltage and insufficient cycle characteristics. In the all solid state secondary batteries of Test Nos. c12 to c14 of the comparative examples in which the polymer not having hetero atoms and/or carbon-carbon unsaturated bonds not contributing to aromaticity in the main chain, the battery voltages were insufficient.

Meanwhile, in all solid state secondary batteries in which the electrolytic crosslinking polymer being used in the present invention was crosslinked and the crosslinked polymer from which at least carbon-carbon unsaturated bonds not contributing to aromaticity were removed was used for the respective compositions, since the polymer is crosslinked and has a high molecular weight, the polymer did not perform a sufficient function as a binder between the active material and the inorganic solid electrolyte, and a favorable battery voltage and favorable cycle characteristics were not exhibited.

The present invention has been described together with the embodiment; however, unless particularly specified, the present inventors do not intend to limit the present invention in any detailed portion of the description and consider that the present invention is supposed to be broadly interpreted within the concept and scope of the present invention described in the claims.

### EXPLANATION OF REFERENCES

1: negative electrode collector
2: negative electrode active material layer
3: solid electrolyte layer
4: positive electrode active material layer
5: positive electrode collector
6: operation portion
10: all solid state secondary battery
11: upper portion-supporting plate
12: lower portion-supporting plate
13: coin battery
14: coin case
15: electrode sheet for secondary battery
S: screw

What is claimed is:

1. An all solid state secondary battery comprising:
a positive electrode active material layer:
an inorganic solid electrolyte layer; and
a negative electrode active material layer in this order,
wherein at least one layer of the positive electrode active material layer, the inorganic solid electrolyte layer, or the negative electrode active material layer includes a polymer and an inorganic solid electrolyte,
the polymer is a crosslinking polymer having both of hetero atoms and carbon-carbon unsaturated bonds not contributing to aromaticity in a main chain, and
the inorganic solid electrolyte contains a metal belonging to Group I or II of the periodic table and has an ion conductivity of the metal being contained.

2. The all solid state secondary battery according to claim 1,
wherein the crosslinking polymer has at least one structural unit selected from Formula (1) or (2) below in the main chain, 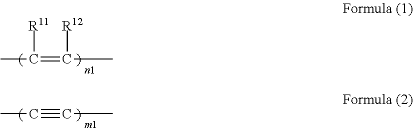
in Formula (1) or (2), R¹¹ and R¹² each independently represent a hydrogen atom, an alkyl group, an aryl group, or a heteroaryl group; R¹¹ and R¹² may be bonded to each other and form a ring not having aromaticity; stereoisomerism of R¹¹ and R¹² may be any one of cis and trans; and n1 and m1 each independently represent an integer of 1 or more and 10 or less.

3. The all solid state secondary battery according to claim 1,
wherein the crosslinking polymer has at least one structural unit selected from Formula (1a) or (2a) below in the main chain, 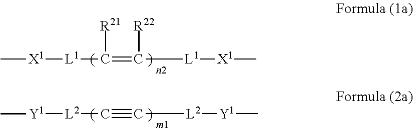
in Formula (1a) or (2a), R²¹ and R²² each independently represent a hydrogen atom, an alkyl group, an aryl group, or a heteroaryl group; R²¹ and R²² may be bonded to each other and form a ring not having aromaticity; stereoisomerism of R²¹ and R²² may be any one of cis and trans; n2 and m2 each independently represent an integer of 1 or more and 5 or less; L¹ and L² each independently represent a single bond or a divalent linking group; two L¹'s or two L²'s may be bonded to each other and form a ring not having aromaticity; X¹ and Y¹ each independently represent an oxygen atom, >NR^{N}, >CO, or a combination thereof; R^{N} represents a hydrogen atom or an alkyl group; R^{N} and L¹ or R^{N} and L² may be bonded to each other and form a ring not having aromaticity; a plurality of L¹'s, L²'s, X¹'s, and Y¹'s may be identical to or different from each other.

4. The all solid state secondary battery according to claim 1,
wherein the number of the carbon-carbon unsaturated bonds not contributing to aromaticity in the main chain of the crosslinking polymer is set to one in the case of a double bond or two in the case of a triple bond, and
an unsaturated bond percentage calculated using Expression (3) below has a relationship of Expression (4) below,
unsaturated bond percentage=(the total number of the carbon-carbon unsaturated bonds not contributing to aromaticity in the main chain)/(the total number of all carbon-carbon bonds forming the main chain)×100 Expression (3)
0.1%<unsaturated bond percentage<50% Expression (4).

5. The all solid state secondary battery according to claim 1,
wherein the crosslinking polymer has a bond represented by Formula (5) blow in the main chain, 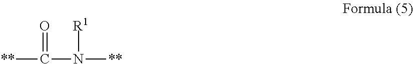
in Formula (5), R¹ represents a hydrogen atom, an alkyl group, an aryl group, or a group being bonded to the nitrogen atom in Formula (5) through a carbonyl group; R¹ may be bonded to an organic group to which C(═O) is linked and form a ring; and ** represents a linking portion.

6. The all solid state secondary battery according to claim 1,
wherein the crosslinking polymer is polyurethane.

7. The all solid state secondary battery according to claim 1,
wherein the crosslinking polymer includes at least one functional group selected from a group of functional groups (I),
Group of functional groups (I)
a carboxy group, a sulfonate group, a phosphoric acid group, a hydroxy group, —CONR^{NA}₂, a cyano group, NR^{NA}₂, a mercapto group, an epoxy group, and a (meth)acryl group, where R^{NA} represents a hydrogen atom, an alkyl group, or an aryl group.

8. The all solid state secondary battery according to claim 1,
wherein a mass average molecular weight of the crosslinking polymer is 10,000 or more and less than 500,000.

9. The all solid state secondary battery according to claim 1,
wherein a glass transition temperature of the crosslinking polymer is lower than 50° C.

10. The all solid state secondary battery according to claim 1,
wherein at least one layer of the positive electrode active material layer, the negative electrode active material layer, or the inorganic solid electrolyte layer further contains a lithium salt.

11. The all solid state secondary battery according to claim 1,
wherein the inorganic solid electrolyte is a sulfide-based inorganic solid electrolyte.

12. The all solid state secondary battery according to claim 1,
wherein the inorganic solid electrolyte is an oxide-based inorganic solid electrolyte.

13. The all solid state secondary battery according to claim 12,
wherein the inorganic solid electrolyte is selected from compounds of formulae below,
LiₓₐLa_{ya}TiO₃
xa=0.3 to 0.7, ya=0.3 to 0.7
Li₇La₃Zr₂O₁₂
Li_{3.5}Zn_{0.25}GeO₄
LiTi₂P₃O₁₂
Li_{1+xb+yb}(Al, Ga)_{xb}(Ti, Ge)_{2-xb}Si_{yb}P_{3-yb}O₁₂
0≦xb≦1, 0≦yb≦1
Li₃PO₄
LiPON
LiPOD
D is at least one selected from Ti, V, Cr, Mn, Fe, Co, Ni, Cu, Zr, Nb, Mo, Ru, Ag, Ta, W, Pt, or Au
LiAON
A is at least one selected from Si, B, Ge, Al, C, or Ga.

14. A solid electrolyte composition being used for an all solid state secondary battery, comprising:
a crosslinking polymer having both of hetero atoms and carbon-carbon unsaturated bonds not contributing to aromaticity in a main chain; and
an inorganic solid electrolyte containing a metal belonging to Group I or II of the periodic table and having an ion conductivity of the metal being contained.

15. The solid electrolyte composition according to claim 14, comprising:
0.1 parts by mass or more and 20 parts by mass or less of the crosslinking polymer with respect to 100 parts by mass of the inorganic solid electrolyte.

16. An electrode sheet for a battery,
wherein a film of the solid electrolyte composition according to claim 14 is formed on a metal foil.

17. A method for manufacturing an electrode sheet for a battery,
wherein a film of the solid electrolyte composition of claim 14 is formed on a metal foil.

18. A method for manufacturing an all solid state secondary battery,
wherein an all solid state secondary battery is manufactured using the electrode sheet for a battery according to claim 16.

19. An all solid state secondary battery which is formed by crosslinking the crosslinking polymer by charging or discharging the all solid state secondary battery according to claim 1 at least once.
